(19) United States
(12) Patent Application Publication
(10) Pub. No.: US 2010/0173495 A1
(43) Pub. Date: Jul. 8, 2010

(54) SUBSTRATE PROCESSING APPARATUS USING A BATCH PROCESSING CHAMBER

(75) Inventors: Randhir Thakur, San Jose, CA (US); Steve G. Ghanayem, Los Altos, CA (US); Joseph Yudovsky, Campbell, CA (US); Aaron Webb, Austin, TX (US); Adam Alexander Brailove, Gloucester, MA (US); Nir Merry, Mt. View, CA (US); Vinay K. Shah, San Mateo, CA (US); Andreas G. Hegedus, Burlingame, CA (US)

Correspondence Address: PATTERSON & SHERIDAN, LLP - - APPM/TX, 3040 POST OAK BOULEVARD, SUITE 1500, HOUSTON, TX, 77056, US

(73) Assignee: APPLIED MATERIALS, INC.

(21) Appl. No.: 12/724,935

(22) Filed: Mar. 16, 2010

Related U.S. Application Data
(63) Continuation of application No. 11/286,063, filed on Nov. 22, 2005.
(60) Provisional application No. 60/630,501, filed on Nov. 22, 2004.
(60) Provisional application No. 60/642,877, filed on Jan. 10, 2005.

(51) Int. Cl. H01L 21/302; H01L 21/316; H01L 21/314; C23C 16/00

(52) U.S. Cl. 438/694; 438/785; 438/778; 438/763; 118/719; 257/E21.274; 257/E21.28; 257/E21.214; 257/E21.269

(57) ABSTRACT

Aspects of the invention include a method and apparatus for processing a substrate using a multi-chamber processing system (e.g., a cluster tool) adapted to process substrates in one or more batch and/or single substrate processing chambers to increase the system throughput. In one embodiment, a system is configured to perform a substrate processing sequence that contains batch processing chambers only, or batch and single substrate processing chambers, to optimize throughput and minimize processing defects due to exposure to a contaminating environment. In one embodiment, a batch processing chamber is used to increase the system throughput by performing a process recipe step that is disproportionately long compared to other process recipe steps in the substrate processing sequence that are performed on the cluster tool. In another embodiment, two or more batch chambers are used to process multiple substrates using one or more of the disproportionately long processing steps in a processing sequence. Aspects of the invention also include an apparatus and method for delivering a precursor to a processing chamber so that a repeatable ALD or CVD deposition process can be performed.

### CROSS-REFERENCE TO RELATED APPLICATIONS

This application is a continuation of a co-pending U.S. patent application Ser. No. 11/286,063 (Attorney Docket No. 09526), filed Nov. 22, 2005, which claims benefit of U.S. Provisional Patent Application Ser. No. 60/630,501, filed Nov. 22, 2004, and United States Provisional Patent Application Serial No. 60/642,877, filed Jan. 10, 2005. All the aforementioned patent applications are herein incorporated by reference.

### BACKGROUND OF THE INVENTION

1. Field of the Invention

Embodiments of the invention generally relates to an integrated processing system configured to perform processing sequences which include both single substrate and batch deposition processing modules.

2. Description of the Related Art

The process of forming semiconductor device is commonly done in a multi-chamber processing system (e.g., a cluster tool) which has the capability to process substrates, (e.g., semiconductor wafers) in a controlled processing environment. A typical controlled processing environment will include a vacuum system that has a mainframe which houses a substrate transfer robot which transports substrates between a load lock and multiple vacuum processing chambers which are connected to the mainframe. The controlled processing environment has many benefits which include minimizing contamination of the substrate surfaces during transfer and during completion of the various substrate processing steps. Processing in a controlled environment thus reduces the number of generated defects and improves device yield.

The effectiveness of a substrate fabrication process is often measured by two related and important factors, which are device yield and the cost of ownership (COO). These factors are important since they directly affect the cost to produce an electronic device and thus a device manufacturer's competitiveness in the market place. The COO, while affected by a number of factors, is greatly affected by the system and chamber throughput or simply the number of substrates per hour processed using a desired processing sequence. A process sequence is generally defined as the sequence of device fabrication steps, or process recipe steps, completed in one or more processing chambers in the cluster tool. A process sequence may generally contain various substrate (or wafer) fabrication processing steps. If the substrate throughput in a cluster tool is not robot limited, the longest process recipe step will generally limit the throughput of the processing sequence, increase the COO and possibly make a desirable processing sequence impractical.

Conventional cluster tool process sequencing utilizes a plurality of single substrate processing chambers that are adapted to perform the desired semiconductor device fabrication process. Typical system throughput for the conventional fabrication processes, such as a PVD tool or a CVD tool, running a typical deposition process will generally be between 30 to 60 substrates per hour. For a two to four process chamber system, having all the typical pre- and post-processing steps will translate to a maximum processing time of about 1 to 2 minutes. The allowable maximum processing step time may vary based on the number of parallel processes or redundant chambers contained in the system.

The push in the industry to shrink the size of semiconductor devices to improve device processing speed and reduce the generation of heat by the device, has caused the industry's tolerance to process variability to shrink. To meet these tighter process requirements, the industry has developed a host of new processes which meet the tighter process window requirements, but these processes often take a longer time to complete. For example, some ALD processes can require a chamber processing time from about 10 to about 200 minutes to deposit a high quality layer on the surface of the substrate, which would lead to a substrate processing sequence throughput on the order of about 0.3 to about 6 substrates per hour. While forced to choose such processes due to device performance requirements, the cost to fabricate the devices in a conventional single substrate processing chamber will increase due to the low substrate throughput. Also, while it is possible to add more tools to the wafer fab to meet the desired number of wafer starts per week (or substrate starts per week), it is often impractical to increase the number of process chambers or tools without significantly increasing the size of a wafer fab and the staff to run the tools, because these are often the most expensive aspects of the substrate fabrication process.

Due to the shrinking size of semiconductor devices and the ever increasing device performance requirements, the amount of allowable variability of the device fabrication process uniformity and repeatability has greatly decreased. One factor that can affect device performance variability and repeatability is known as the “queue time.” Queue time is generally defined as the time a substrate can be exposed to the atmospheric or other contaminants after a first process has been completed on the substrate before a second process must be completed on the substrate to prevent some adverse affect on the fabricated device's performance. If the substrate is exposed to atmospheric or other sources of contaminants for a time approaching or longer than the allowable queue time, the device performance may be affected by the contamination of the interface between the first and second layers. Therefore, for a process sequence that includes exposing a substrate to atmospheric or other sources of contamination, the time the substrate is exposed to these sources must be controlled or minimized to prevent device performance variability. Therefore, a useful electronic device fabrication process must deliver uniform and repeatable process results, minimize the affect of contamination, and also meet a desired throughput to be considered for use in a substrate processing sequence.

Therefore, there is a need for a system, a method and an apparatus that can process a substrate so that it can meet the required device performance goals and increase the system throughput and thus reduce the process sequence COO.

### SUMMARY OF THE INVENTION

The present invention generally provides a substrate processing apparatus comprising a factory interface having a transfer region that is generally maintained at atmospheric pressure, a cool plate that is adapted to heat and/or cool a substrate, a batch capable substrate processing chamber that is in communication with the transfer region of the factory interface, and a transfer robot positioned in the transfer region that is adapted to transfer one or more substrates between the cool plate and the batch capable substrate processing chamber.

Embodiments of the invention further provide a substrate processing apparatus comprising a factory interface having a transfer region that is generally maintained at atmospheric pressure, a cool plate that is adapted to heat and/or cool a substrate, a batch capable substrate processing chamber assembly that is in communication with the transfer region of the factory interface, wherein the batch capable substrate processing chamber assembly comprises a substrate processing region having one or more walls that form an internal process volume, a substrate buffer region having one or more walls that form an internal buffer volume, wherein the substrate buffer region is positioned adjacent to the substrate processing region, and a process cassette that is adapted to support two or more substrates, wherein the process cassette is transferable between the internal buffer volume and the internal process volume by use of a lift mechanism, and a transfer robot positioned in the transfer region that is adapted to transfer one or more substrates between the cool plate and the process cassette.

Embodiments of the invention further provide a substrate processing apparatus comprising a pod that is adapted to contain two or more substrates, a factory interface having a transfer region that is generally maintained at atmospheric pressure, a first batch capable substrate processing chamber assembly that is in communication with the transfer region of the factory interface, wherein the first batch capable substrate processing chamber assembly comprises a first substrate processing region having one or more walls that form a first internal process volume, a first transfer region having one or more walls that form a first internal buffer volume, wherein the first transfer region is positioned vertically adjacent to the first substrate processing region, and a first process cassette that is adapted to support two or more substrates, wherein the first process cassette is transferable between the first internal buffer volume and the first internal process volume by use of a lift mechanism, a second batch capable substrate processing chamber assembly that is in communication with the transfer region of the factory interface, wherein the second batch capable substrate processing chamber assembly comprises a second substrate processing region having one or more walls that form a second internal process volume, a second transfer region having one or more walls that form a second internal buffer volume, wherein the second transfer region is positioned vertically adjacent to the second substrate processing region, and a second process cassette that is adapted to support two or more substrates, wherein the second process cassette is transferable between the second internal buffer volume and the second internal process volume by use of a lift mechanism, a vacuum pump that is adapted to reduce the pressure in at least one region selected from a group consisting of the first internal process volume, the second internal process volume, the first internal buffer volume, and the second internal buffer volume, and a transfer robot positioned in the transfer region that is adapted to transfer one or more substrates between the pod and the first process cassette or second process cassette.

Embodiments of the invention further provide a substrate processing apparatus comprising a factory interface system having a transfer region that is generally maintained at atmospheric pressure, two or more batch capable substrate processing chambers that are each in communication with the transfer region, wherein the two or more batch capable substrate processing chambers comprise a substrate processing region having one or more walls that form an internal process volume, a substrate buffer region having one or more walls that form an internal buffer volume, wherein the substrate buffer region is positioned vertically adjacent to the substrate processing region, a process cassette that is adapted to support two or more substrates, wherein the process cassette is transferable between the internal buffer volume and the internal process volume by use of a lift mechanism, and a shutter positioned between the substrate processing region and the substrate buffer region, wherein the shutter is adapted to be sealably positioned to isolate the internal process volume from the internal buffer volume, a cool down plate positioned in the transfer region of the factory interface, and a robot mounted in the transfer chamber that is adapted to transfer substrates between the cool down plate and the two or more batch substrate processing chambers.

Embodiments of the invention further provide a substrate processing apparatus comprising a pod that is adapted to contain two or more substrates, a factory interface having a transfer region that is generally maintained at atmospheric pressure, a batch capable substrate processing chamber assembly that is in communication with the transfer region of the factory interface, wherein the batch capable substrate processing chamber assembly comprises a substrate processing region having one or more walls that form an internal process volume, a substrate buffer region having one or more walls that form an internal buffer volume, wherein the substrate buffer region is positioned vertically adjacent to the substrate processing region, a process cassette that is adapted to support two or more substrates, and a lift mechanism that is adapted to transfer the process cassette between the internal buffer volume and the internal process volume, a first chamber comprising a first cool plate that is adapted to heat and/or cool a substrate, and a first robot that is adapted to transfer one or more substrates between the first cool plate and the process cassette, a single substrate processing chamber that is in communication with the transfer region, wherein the single substrate processing chamber has one or more walls that form a single substrate internal process volume, a second chamber comprising a second cool plate that is adapted to heat and/or cool a substrate, and a second robot that is adapted to transfer one or more substrates between the second cool plate and the single substrate processing chamber, and a third robot that is positioned in the transfer region and is adapted to transfer one or more substrates between the first chamber, the second chamber, and the pod.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a plan view of a typical prior art processing system for semiconductor processing wherein the present invention may be used to advantage.

FIG. 2A is a plan view of a typical processing system containing a batch processing chamber and a single processing chamber adapted for semiconductor processing wherein the present invention may be used to advantage.

FIG. 2B is a plan view of a typical processing system containing two batch processing chambers and a single processing chamber adapted for semiconductor processing wherein the present invention may be used to advantage.

FIG. 2C is a plan view of a typical atmospheric transfer processing system containing a batch processing chamber and a single processing chamber adapted for semiconductor processing wherein the present invention may be used to advantage.

FIG. 2D is a plan view of a typical atmospheric transfer processing system containing a batch processing chamber and two single processing chambers that are adapted for semiconductor processing wherein the present invention may be used to advantage.

FIG. 2E is a plan view of a typical atmospheric transfer processing system containing a two batch processing chambers that are adapted for semiconductor processing wherein the present invention may be used to advantage.

FIG. 2F is a plan view of a typical atmospheric transfer processing system containing two batch processing chambers that are adapted for semiconductor processing wherein the present invention may be used to advantage.

FIG. 2G is a side cross-sectional view of a typical atmospheric transfer processing system containing a batch processing chamber that may be adapted for semiconductor processing wherein the present invention may be used to advantage.

FIG. 2H is a side cross-sectional view of a typical atmospheric transfer processing system containing a batch processing chamber that may be adapted for semiconductor processing wherein the present invention may be used to advantage.

FIG. 2I is a plan view of a typical processing system containing a batch processing chambers adapted for semiconductor processing wherein the present invention may be used to advantage.

FIG. 3 is a side view of a batch processing chamber in accordance with the present invention.

FIG. 4 is a top view of the batch processing chamber of FIG. 3.

FIG. 5 is bottom view of the batch processing chamber of FIG. 3.

FIG. 6 is a cross-sectional view of the batch processing chamber of FIG. 3 with the cassette in a loading/unloading position (bottom heaters not shown).

FIG. 7 is a cross-sectional view of the batch processing chamber of FIG. 3 with the cassette in a processing position (bottom heaters not shown).

FIG. 8 is a top cross-sectional view of the upper section of the chamber of the batch processing chamber of FIG. 3.

FIG. 8A is a top cross-sectional view of a wall of the upper section of the chamber of the batch processing chamber of FIG. 8.

FIG. 8B is a top cross-sectional view of the upper section of the chamber of the batch processing chamber of FIG. 3 having semicircular heat shields.

FIG. 9 is schematic illustration of gas delivery and exhaust manifold sections of the chamber of the batch processing chamber of FIG. 3.

FIG. 10 is a schematic illustration of a precursor delivery system for delivering a processing gas to the batch processing chamber of FIG. 3.

FIG. 10A is a schematic illustration of a precursor delivery system for delivering a processing gas to the batch processing chamber of FIG. 3.

FIG. 11 is a cross-sectional view of a prior art batch processing vertical diffusion furnace chamber.

FIG. 12 is a schematic illustration of a convective type precursor gas flow through the batch processing chamber of FIG. 3.

FIG. 13A is a plan view of a typical processing system that schematically illustrates a substrate transfer path for a substrate processing sequence wherein the present invention may be used to advantage.

FIG. 13B is a plan view of a typical processing system that schematically illustrates a substrate transfer path for a substrate processing sequence wherein the present invention may be used to advantage.

FIG. 13C is a plan view of a typical processing system that schematically illustrates a substrate transfer path for a substrate processing sequence wherein the present invention may be used to advantage.

FIG. 13D is a plan view of a typical processing system that schematically illustrates a substrate transfer path for a substrate processing sequence wherein the present invention may be used to advantage.

FIG. 13E is a plan view of a typical processing system, shown in FIG. 2C, that schematically illustrates a substrate transfer path for a substrate processing sequence wherein the present invention may be used to advantage.

FIG. 13F is a plan view of a typical processing system, shown in FIG. 2C, that schematically illustrates a substrate transfer path for a substrate processing sequence wherein the present invention may be used to advantage.

FIG. 14A illustrates process recipe steps used in the substrate processing sequence illustrated in FIGS. 13A.

FIG. 14B illustrates process recipe steps used in the substrate processing sequence illustrated in FIGS. 13B.

FIG. 14C illustrates another group of process recipe steps used in the substrate processing sequence illustrated in FIGS. 13C.

FIG. 14D illustrates another group of process recipe steps used in the substrate processing sequence illustrated in FIGS. 13D.

FIG. 14E illustrates another group of process recipe steps used in the substrate processing sequence illustrated in FIGS. 13E.

FIG. 14F illustrates another group of process recipe steps used in the substrate processing sequence illustrated in FIGS. 13F.

FIG. 15A is a cross-sectional view of a capacitor structure which can be formed using embodiments of the invention.

FIG. 15B is a magnified view of one area of the capacitor structure shown in FIG. 15A.

FIG. 15C illustrates a group of process recipe used to form the capacitor structure illustrated in FIG. 15A, and by following the process sequence illustrated in FIG. 15D.

FIG. 15D is a plan view of a typical processing system that schematically illustrates a substrate transfer path for a substrate processing sequence wherein the present invention may be used to advantage.

### DETAILED DESCRIPTION

The present invention generally provides an apparatus and method for processing substrates using a multi-chamber processing system (e.g., a cluster tool) adapted to process substrates in one or more batch and single substrate processing chambers to increase the system throughput. The term batch processing chamber, or batch capable processing chamber, is meant to generally describe a chamber that can process two or more substrates at one time. In one embodiment, a batch processing chamber is used to increase the system throughput by performing a process recipe step that is disproportionately long compared to other process recipe steps in the substrate processing sequence that are performed on the cluster tool. In another embodiment, two or more batch chambers are used to process multiple substrates using one or more of the disproportionately long processing steps in a processing sequence. In one aspect of the invention, a system controller is utilized to control the number of substrates (or lot size) processed in the batch processing chamber to optimize a processing sequence system throughput while minimizing the time the substrates remain idle after being processed in the batch processing chamber before they are processed in the next processing chamber. In general, the next processing chamber may be another batch processing chamber or a single substrate processing chamber. The invention is illustratively described below in reference to a Centura RTM, available from FEP, a division of Applied Materials, Inc., Santa Clara, Calif.

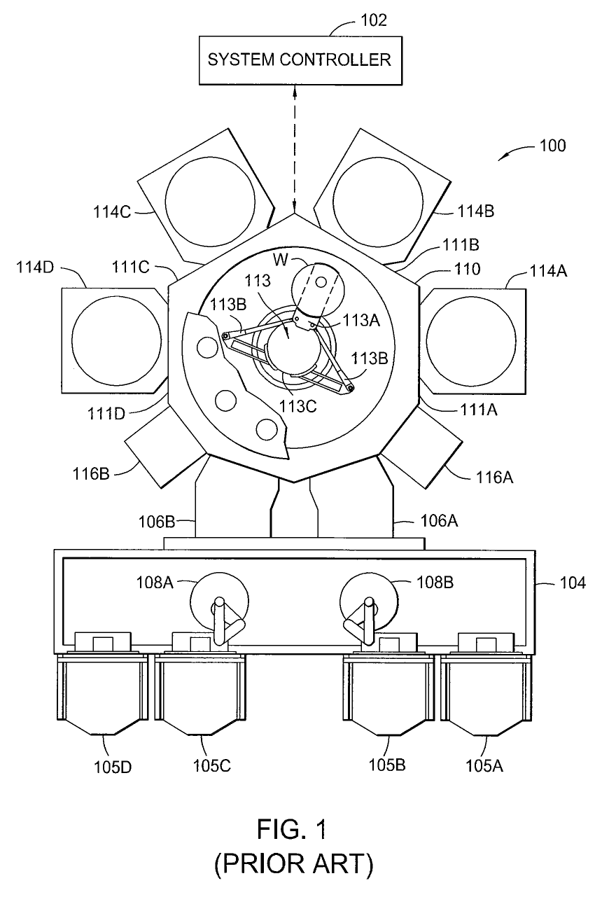

Embodiments of the invention have particular advantages in a cluster tool which has the capability to process substrates in single substrate processing chambers and batch type processing chambers. A cluster tool is a modular system comprising multiple chambers which perform various functions in the electronic device fabrication process. As shown in FIG. 1, the multiple chambers are mounted to a central transfer chamber 110 which houses a robot 113 adapted to shuttle substrates between the chambers. The transfer chamber 110 is typically maintained at a vacuum condition and provides an intermediate stage for shuttling substrates from one chamber to another and/or to a load lock chamber positioned at a front end of the cluster tool.

FIG. 1 is a plan view of a typical cluster tool 100 for electronic device processing wherein the present invention may be used to advantage. Two such platforms are the Centura RTM and the Endura RTM both available from Applied Materials, Inc., of Santa Clara, Calif. The details of one such staged-vacuum substrate processing system are disclosed in U.S. Pat. No. 5,186,718, entitled “Staged-Vacuum Substrate Processing System and Method,” Tepman et al., issued on Feb. 16, 1993, which is incorporated herein by reference. The exact arrangement and combination of chambers may be altered for purposes of performing specific steps of a fabrication process.

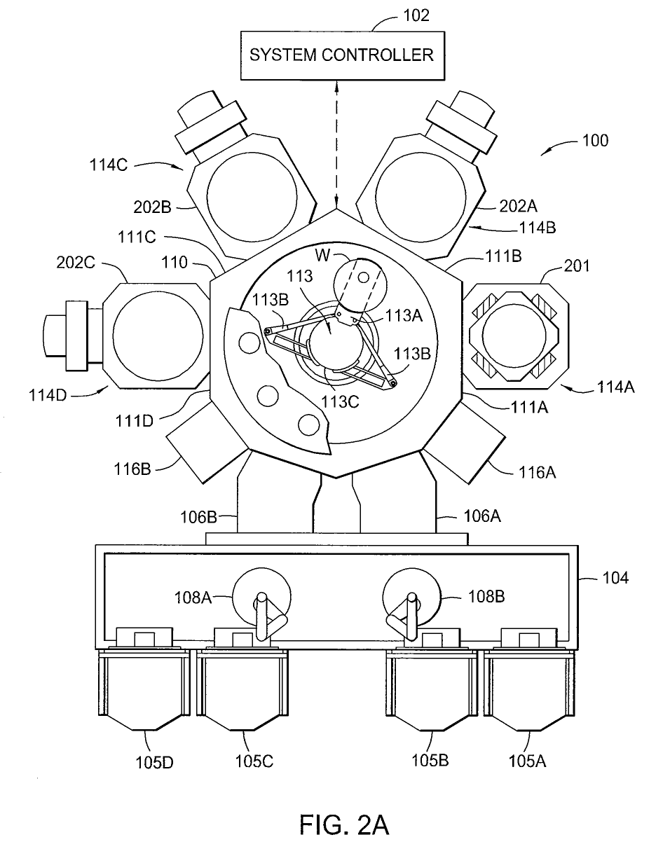

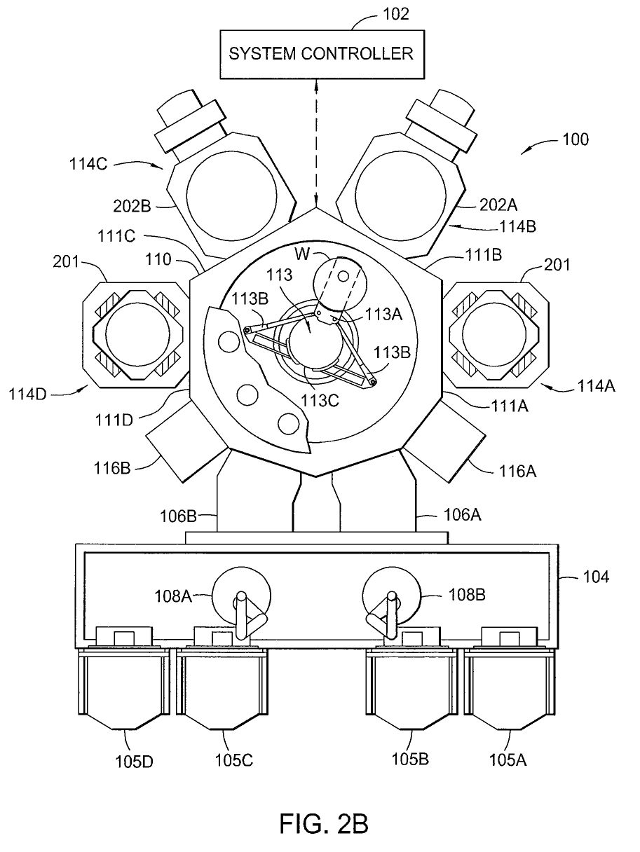

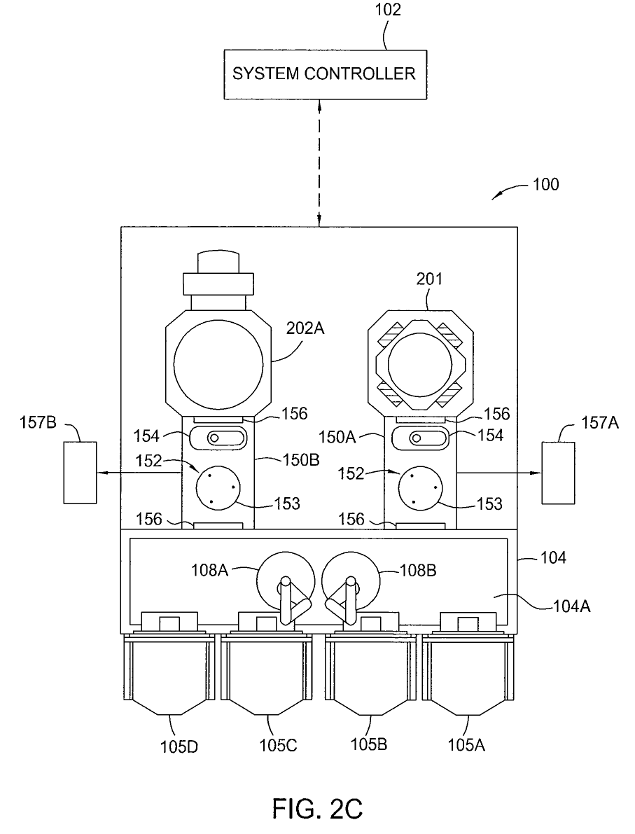

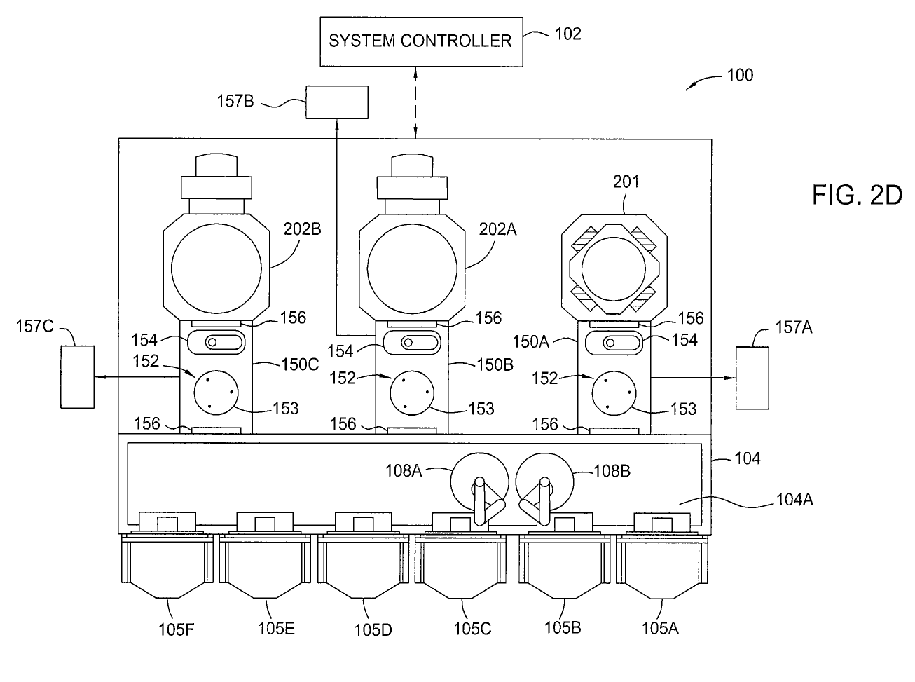

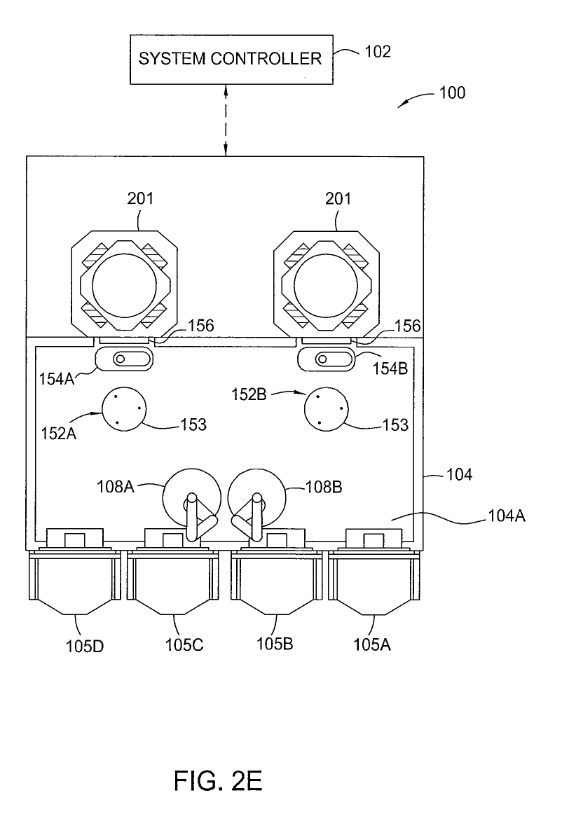

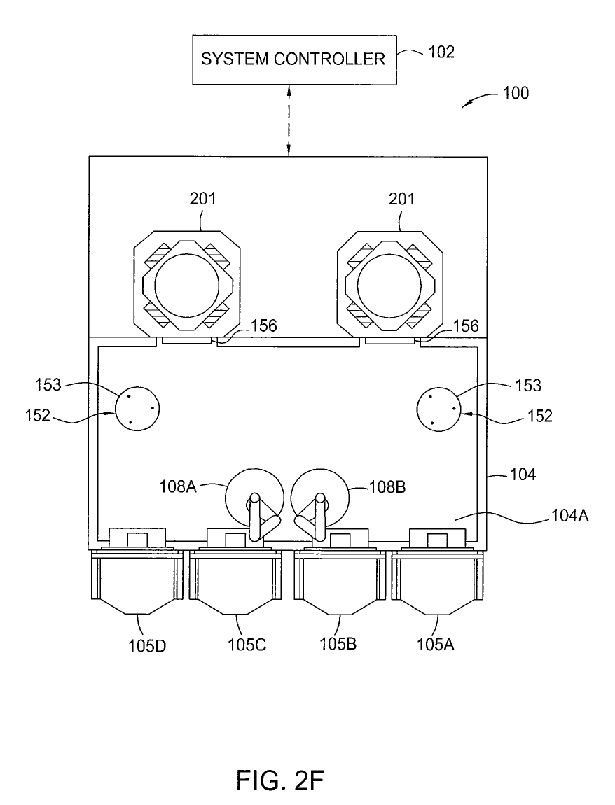

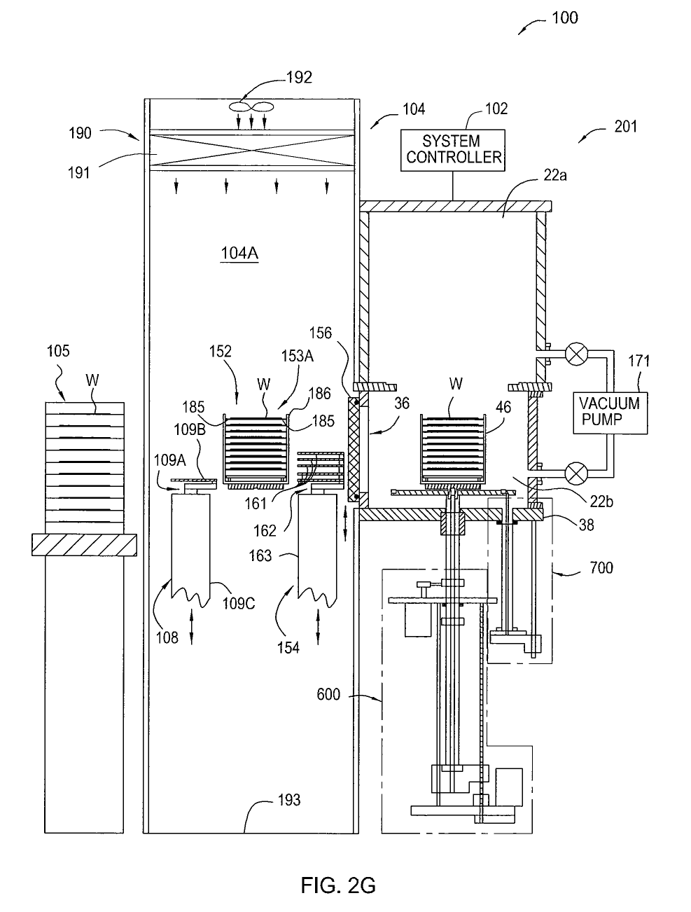

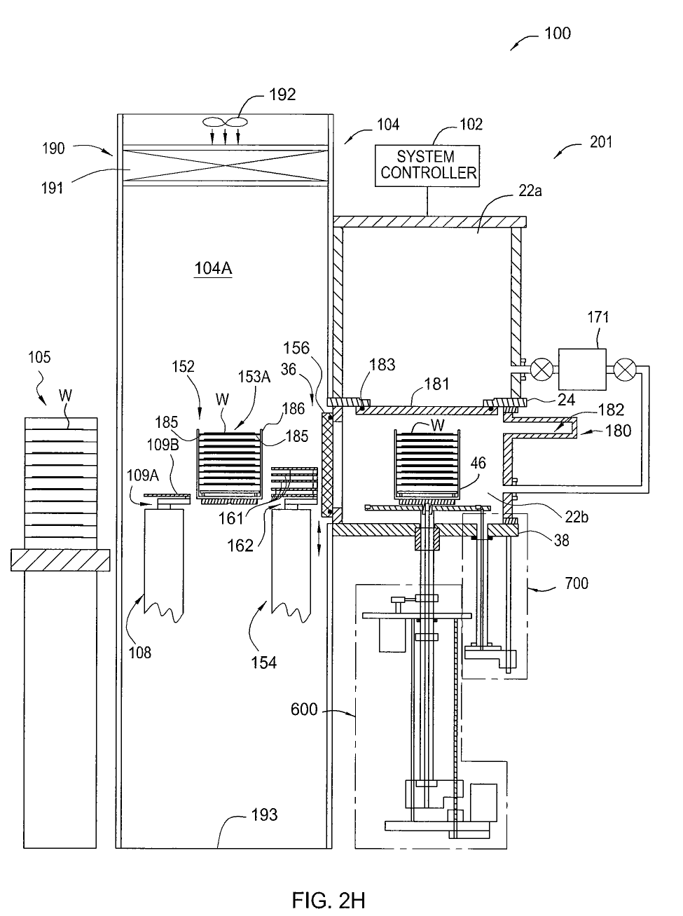

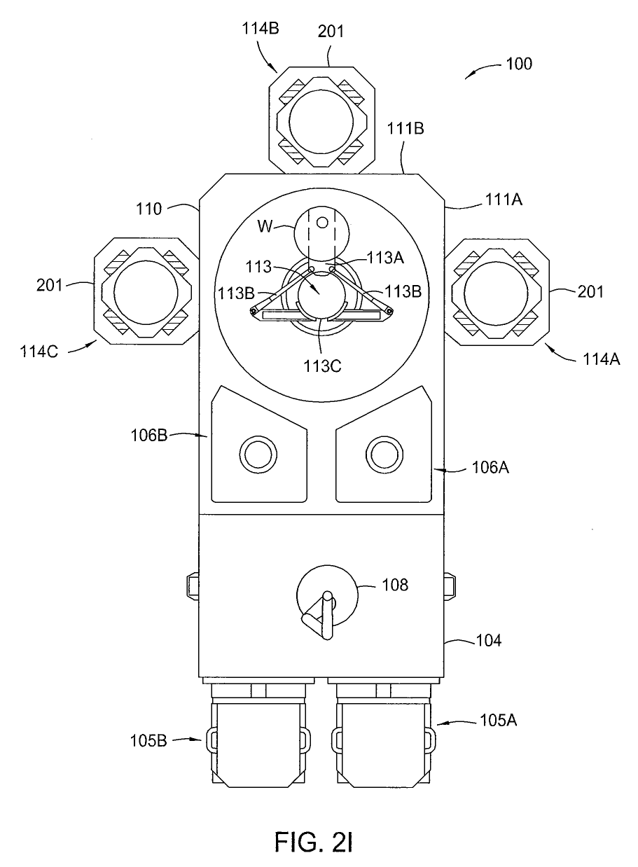

In accordance with aspects of the present invention, the cluster tool 100 generally comprises a plurality of chambers and robots and is preferably equipped with a system controller 102 programmed to control and carry out the various processing methods and sequences performed in the cluster tool 100. FIG. 2A illustrates one embodiment, in which a batch processing chamber 201 is mounted in position 114A on the transfer chamber 110 and three single substrate processing chambers 202A-C are mounted in positions 114B-D on the transfer chamber 110. The batch processing chamber 201 may placed in one or more of the other positions, for example positions 114B-D, to improve hardware integration aspects of the design of the system or to improve substrate throughput. In some embodiments, not all of the positions 114A-D are occupied to reduce cost or complexity of the system.

FIG. 2B illustrates one embodiment, having two batch chambers 201 that are mounted to two of the positions 114A-D and the other positions may contain a single substrate processing chamber. While FIG. 2B illustrates two batch processing chambers 201 mounted in positions 114A and 114D, this configuration is not intended to limit the scope of the present invention since the position or number of batch processing chambers is not limited to the various aspects of the invention described herein, and thus one or more batch chambers 201 may be positioned in any one of the positions 114A-D.

Referring to FIGS. 2A and 2B, an optional front-end environment 104 (also referred to herein as a Factory Interface or FI) is shown positioned in selective communication with a pair of load lock chambers 106. Factory interface robots 108A-B disposed in the transfer region 104A of the front-end environment 104 are capable of linear, rotational, and vertical movement to shuttle substrates between the load locks 106 and a plurality of pods 105 which are mounted on the front-end environment 104. The front-end environment 104 is generally used to transfer substrates from a cassette (not shown) seated in the plurality of pods 105 through an atmospheric pressure clean environment/enclosure to some desired location, such as a process chamber (e.g., load lock 106, substrate buffer/cool down position 152, batch processing chamber 201, and/or single substrate processing chambers 202). The clean environment found in the transfer region 104A of the front-end environment 104 is generally provided by use of an air filtration process, such as passing air through a high efficiency particulate air (HEPA) filter, for example. A front-end environment, or front-end factory interface, is commercially available from Applied Materials Inc. of Santa Clara, Calif.

The load locks 106 provide a first vacuum interface between the front-end environment 104 and a transfer chamber 110. In one embodiment, two load locks 106 are provided to increase throughput by alternatively communicating with the transfer chamber 110 and the front-end environment 104. Thus, while one load lock 106 communicates with the transfer chamber 110, a second load lock 106 can communicate with the front-end environment 104. In one embodiment, the load locks 106 are a batch type load lock that can receive two or more substrates from the factory interface, retain the substrates while the chamber is sealed and then evacuated to a low enough vacuum level to transfer of the substrates to the transfer chamber 110. Preferably, the batch load locks can retain from 25 to 50 substrates at one time. In one embodiment, the load locks 106A-B may be adapted to cool down the substrates after processing in the cluster tool. In one embodiment, the substrates retained in the load lock may be cooled by convection caused by a flowing gas from a gas source inlet (not shown) to a gas exhaust (not shown), which are both mounted in the load lock. In another embodiment, the load lock may be fitted with a load lock cassette including a plurality of heat conductive shelves (not shown) that can be cooled. The shelves can be interleaved between the substrates retained in the cassette so that a gap exists between the shelves and the substrates. In this embodiment, the shelves cool the substrates radiantly, thereby providing uniform heating or cooling of the substrates so as to avoid damage or warpage of the substrates. In another embodiment, the shelves contact a surface of the substrate to cool the substrate by conducting heat away from its surface.

In one embodiment, the cluster tool 100 is adapted to process substrates at a pressure at or close to atmospheric pressure (e.g., 760 Torr) and, thus, no load locks 106A-B are required as an intermediate chamber between the factory interface and the transfer chamber 110. In this embodiment, the factory interface robots 108A-B will transfer the substrate “W” directly to the robot 113 (not shown) or the factory interface robots 108A-B may transfer the substrate “W” to a pass-through chamber (not shown), which takes the place of the load locks 106A-B, so that the robot 113 and the factory interface robots 108A-B can exchange substrates. The transfer chamber 110 may be continually purged with an inert gas to minimize the partial pressure of oxygen, water, and/or other contaminants in the transfer chamber 110, the processing chambers mounted in positions 114A-D and the service chambers 116A-B. Inert gases that may be used include, for example, argon, nitrogen, or helium. A plurality of slit valves (not shown) can be added to the transfer chamber 110, service chambers 116A-B, and/or process chambers mounted in positions 114A-D to isolate each position from the other positions so that each chamber may be separately evacuated to perform a vacuum process during the processing sequence.

A robot 113 is centrally disposed in the transfer chamber 110 to transfer substrates from the load locks 106 to one of the various processing chambers mounted in positions 114A-D and service chambers 116A-B. The robot 113 generally contains a blade assembly 113A, arm assemblies 113B which are attached to the robot drive assembly 113C. The robot 113 is adapted to transfer the substrate “W” to the various processing chambers by use of commands sent from the system controller 102. A robot assembly that may be adapted to benefit from the invention is described in commonly assigned U.S. Pat. No. 5,469,035, entitled “Two-axis magnetically coupled robot”, filed on Aug. 30, 1994; U.S. Pat. No. 5,447,409, entitled “Robot Assembly” filed on Apr. 11, 1994; and U.S. Pat. No. 6,379,095, entitled Robot For Handling Semiconductor Substrates”, filed on Apr. 14, 2000, which are hereby incorporated by reference in their entireties.

Referring to FIGS. 2A and 2B, the processing chambers 202A-C mounted in one of the positions 114A-D may perform any number of processes such as preclean, PVD, CVD, ALD, decoupled plasma nitridation (DPN), rapid thermal processing (RTP), metrology techniques (e.g., particle measurement, etc.) and etching while the service chambers 116A-B are adapted for degassing, orientation, cool down and the like. In one embodiment, the processing sequence is adapted to form a high-K capacitor structure, where processing chambers 202 may be a DPN chamber, a CVD chamber capable of depositing poly-silicon, and/or a MCVD chamber capable of depositing titanium, tungsten, tantalum, platinum, or ruthenium.

In one aspect of the invention, one or more of the single substrate processing chambers 202A-C may be an RTP chamber which can be used to anneal the substrate before or after performing the batch deposition step. An RTP process may be conducted using an RTP chamber and related process hardware commercially available from Applied Materials Inc. located in Santa Clara, Calif. In another aspect of the invention, one or more of the single substrate processing chambers 202A-C may be a CVD chamber. Examples of such CVD process chambers include DXZ™ chambers, Ultima HDP-CVD™ chamber and PRECISION 5000® chamber, commercially available from Applied Materials, Inc., Santa Clara, Calif.. In another aspect of the invention, one or more of the single substrate processing chambers 202A-C may be a PVD chamber. Examples of such PVD process chambers include Endura™ PVD processing chambers, commercially available from Applied Materials, Inc., Santa Clara, Calif. In another aspect of the invention, one or more of the single substrate processing chambers 202A-C may be a DPN chamber. Examples of such DPN process chambers include DPN Centura™ chamber, commercially available from Applied Materials, Inc., Santa Clara, Calif. In another aspect of the invention, one or more of the single substrate processing chambers 202A-C may be a process/substrate metrology chamber. The processes completed in a process/substrate metrology chamber can include, but are not limited to particle measurement techniques, residual gas analysis techniques, XRF techniques, and techniques used to measure film thickness and/or film composition, such as, ellipsometry techniques.

FIG. 2C illustrates a top view of one embodiment of a cluster tool 100 that contains a batch processing chambers 201 and a single substrate processing chamber 202 which are configured to communicate directly with the front-end environment 104. In this configuration the central transfer chamber 110 and a robot 113, shown in FIGS. 2A-2B are removed from the cluster tool 100 to reduce cost and/or system complexity. In one embodiment, the cluster tool 100 will generally contain a batch chamber 201, a front-end environment 104, a buffer chamber 150 (see item 150A) in communication with the batch chamber 201 and the front-end environment 104, a single substrate processing chamber 202, a buffer chamber 150 (see item 150B) in communication with the single substrate processing chamber 202 and the front-end environment 104, and a system controller 102. In one embodiment, the front-end environment 104 is in communication with an inert gas source (not shown) to purge and minimize the partial pressure of certain contaminants (e.g., oxygen, water, etc.) found in the transfer region 104A of the front-end environment 104.

The buffer chamber (e.g., elements 150A, 150B) generally contains a substrate buffer/cool down position 152 and a substrate transfer mechanism 154. In another aspect of the invention, the buffer chamber is in communication with an inert gas source (not shown) to purge and minimize the partial pressure of certain contaminants (e.g., oxygen, water, etc.) found in the buffer chamber. In one embodiment, the buffer chamber 150 contains a slit valve 156 at the interface between the front-end environment 104 and the buffer chamber 150, and/or a slit valve 156 at the interface between the buffer chamber 150 and the single substrate or batch substrate processing chambers, so that the buffer chamber 150 can be isolated from the front-end environment and/or the single substrate or batch substrate processing chambers. A slit valve that may be adapted for use with the embodiments described herein are described in commonly assigned U.S. Pat. No. 5,226,632, filed on Apr. 10, 1992; and U.S. Pat. No. 4,785,962, filed on Apr. 20, 1987, which are both hereby incorporated by reference in their entireties. In one aspect of the invention the buffer chamber 150 can be further adapted to communicate with a vacuum pump (e.g., element 157A or 157B) to evacuate the buffer chamber 150 and, thus, minimize the concentration of certain contaminants (e.g., oxygen, water, etc.) found in the buffer chamber 150. The vacuum pump may be a turbo pump, rough pump, and/or Roots Blower™ as required to achieve the desired chamber processing pressures.

In one embodiment, the buffer/cool down position 152 contains a cool down plate 153 that is used to actively cool the substrates after being processed in the single substrate or batch processing chambers, so that the factory interface robots 108 can reliably handle the substrates and minimize the detrimental effect of exposing the hot substrate to atmospheric contamination. In one aspect of the invention, the buffer/cool down position 152 may also contain a lift assembly (not shown) which allows a substrate to be received from the factory interface robots 108, or the substrate transfer mechanism 154, and allows the substrate to be raised and lowered to make contact with the cool down plate 153. The cool down plate 153 can be actively cooled by use of a temperature controlled heat exchanging fluid or by use of a thermo-electric device. The substrate transfer mechanism 154 is generally a conventional robot that is adapted to transfer a substrate to and from the buffer/cool down position 152 and the attached substrate processing chamber, by use of commands sent by the system controller 102.

FIG. 2D illustrates a top view of one embodiment of the cluster tool 100 that contains all of the elements as described above and illustrated in FIG. 2C, plus an additional single substrate processing chamber (e.g., element 202B) that is configured to communicate directly with the front-end environment 104. In one aspect, a buffer chamber 150C is positioned between the single substrate processing chamber 202B and the front-end environment 104, and can be pumped down to a vacuum pressure by use of the vacuum pump 157C. In general, embodiments of the invention contemplate configurations where at least one or more batch processing chambers 201 and one or more single substrate processing chambers 202 that are in direct communication with the front-end environment 104. In another embodiment, the cluster tool 100 may contain one or more pods 105, a factory interface robot 108, a buffer chamber 150 and a batch processing chamber 201. In another embodiment, the cluster tool 100 may contain one or more pods 105 (e.g., elements 105A-F), a factory interface robot 108, and one or more batch processing chambers 201.

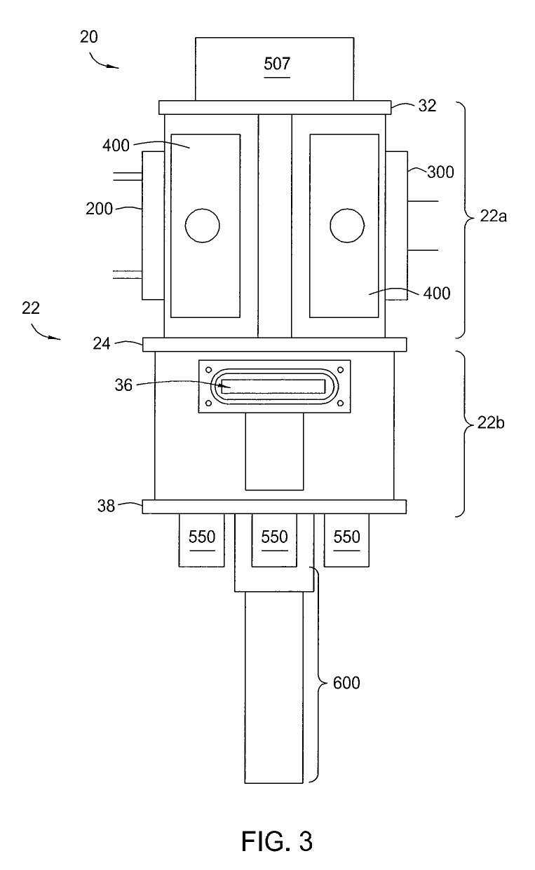

FIG. 2E illustrates a top view of one embodiment of the cluster tool 100 that contains two or more processing chambers (e.g., element 201) that are configured to communicate directly with the front-end environment 104. In this configuration, the buffer chamber (element 150) is part of the transfer region 104A. Therefore, as shown in FIG. 2E, the front-end environment 104 contains the buffer/cool down position 152 and the substrate transfer mechanism 154. While two batch processing chambers 201 are shown in FIG. 2E, this configuration is not intended to be limiting as to the scope of the invention. In one embodiment, the cluster tool 100 generally contains a front-end environment 104, a system controller 102, and two batch chambers 201 that are in communication with the transfer region 104A of the front-end environment 104. In one aspect, a slit valve 156 may be sealably positioned between the buffer volume 22b (FIG. 3) of one or more of the batch processing chambers 201 and the transfer region 104A to isolate the components in the internal volumes of the batch processing chambers 201 from the front-end environment 104.

In one aspect of the cluster tool 100, as illustrated in FIG. 2E, the cool down plate 153 in the buffer/cool down positions 152 and the substrate transfer mechanisms 154 are positioned in the transfer region 104A to improve serviceability and reduce the cluster tool 100 cost and complexity. Generally, in this configuration the factory interface robots (elements 108A and 108B) are adapted to transfer the substrates between one of the pods (elements 105A-105D) and one of the buffer/cool down positions (elements 152A or 152B), and the substrate transfer mechanisms (elements 154A or 154B) are adapted to transfer one or more substrates between their respective buffer/cool down position (elements 152A or 152B) and the buffer volume 22b of their associated batch processing chamber 201. In one aspect, only a one substrate transfer mechanism (not shown) is used to transfer substrates between the buffer/cool down positions (elements 152A or 152B) and either of the batch processing chambers 201.

FIG. 2F illustrates a top view of one embodiment in which the cluster tool 100 contains all of the elements as described above and illustrated in FIG. 2E, minus the substrate transfer mechanisms 154. In this configuration the substrates are transferred between the process chambers (elements 201), the buffer/cool down positions (elements 152A or 152B) and the pods (elements 105A-105D) using one or more factory interface robots (e.g., 108A, 108B). This configuration may be useful to reduce system cost, complexity and the cluster tool footprint.

FIG. 2G is a vertical cross-sectional view of the cluster tool 100 that is intended to illustrate one embodiment of the configurations illustrated in FIG. 2E. In this configuration, as noted above, the cluster tool 100 generally contains one or more pods 105, a front-end environment 104 and one or more processing chambers (e.g., element 201 is shown) that are adapted to communicate directly with the front-end environment 104. The front-end environment 104, as illustrated may generally contain one or more factory interface robots 108, one or more buffer/cool down positions 152, and one or more substrate transfer mechanisms 154. In one aspect, the front-end environment 104 also contains a filtration unit 190 that may contain a filter 191, such as a HEPA filter, and a fan unit 192. The fan unit 192 is adapted to push air through the filter 191, the transferring region 104A and out the base 193 of the front-end environment 104. The factory interface robots 108 may generally contain a conventional SCARA robot 109A, a conventional robot blade 109B and a conventional robot vertical motion assembly 109C that are adapted to transfer substrates from a pod 105 to another desired location in the front-end environment 104.

In one embodiment of the front-end environment 104, each buffer/cool down position 152 is adapted to process a plurality of substrates at once using a batch processing device 153A. In one aspect, the substrates “W” are positioned in a cassette 186 of the batch processing device 153A that includes a plurality of heat conductive shelves 185 (e.g., nine shown in FIG. 2H) that can be heated or cooled using a conventional thermoelectric devices or conventional heat exchanging device, such as a fluid heat exchanger. The shelves 185 are interleaved between the substrates “W” retained in the cassette 186 so that a gap exists between the shelves 185 and the substrates to allow efficient mechanical transfer of the substrates to and from the shelves 185. The shelves 185 are generally adapted to uniformly heat or cool the substrates using radiant, convective and/or conductive type heat transfer, to avoid damage or warpage of the processed substrates. In one aspect, the batch processing device 153A is adapted to heat or cool between about 1 and about 100 substrates at a time, and more preferably between about 2 and about 50 substrates at a time.

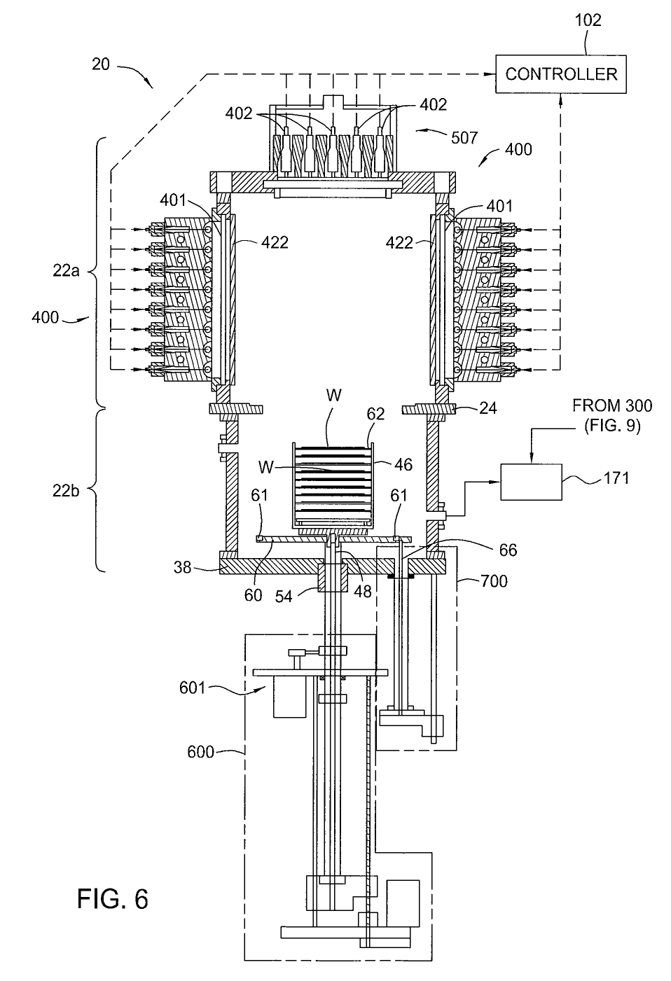

In one embodiment of the front-end environment 104, one or more of the substrate transfer mechanisms 154 are adapted to transfer a plurality of substrates at once. In one aspect, as shown in FIG. 2G, the substrate transfer mechanisms 154 contains a conventional robot 162 (e.g., SCARA robot), a plurality of robot blades 161 (e.g., five shown), and a conventional vertical motion assembly 163 that may be adapted to transfer one or more substrates on each of the robot blades 161 between the buffer/cool down position 152 and the cassette 46 (discussed below; see FIG. 6) located in the buffer volume 22b (discussed below) of the batch processing chamber 201. In this configuration the substrate transfer mechanism 154 is thus in communication with the cassette 46 and the buffer/cool down position 152 chamber and is adapted to transfer multiple substrates simultaneously. The slit valve 156, which is adapted to vacuum isolate the buffer volume 22b of the batch processing chamber 201 from the transferring region 104A during processing, can be moved out of the way by use of an actuator (not shown) so that the substrate transfer mechanism 154 can enter the slit valve opening 36 formed in the buffer volume 22b to access the plurality of substrates positioned in the cassette 46.

In one embodiment, the cluster tool 100 contains only batch processing chambers that are in communication with various automated component so that a user defined processing sequence can be performed using the only batch processing chambers. FIG. 2I illustrates one embodiment, of a cluster tool 100 that contains three batch processing chambers attached to a transfer chamber 110. In one aspect, the transfer chamber 110 is maintained under a vacuum condition by use of a vacuum pump (not shown). This configuration may have many benefits which include minimizing contamination of the substrate surfaces during transfer and also increase system throughput by grouping multiple batch processing chambers that are able to perform a desired processing sequence. Processing in a controlled environment thus reduces the number of generated defects and improves device yield.

FIG. 2I, illustrates one embodiment of the cluster tool 100 that contains a transfer chamber 110 (e.g., three chamber mounting surface 111A-C), a robot 113, three batch processing chambers 201, a front-end environment 104 and two pods 105. In this configuration the batch processing chambers are mounted in positions 114A-C on the transfer chamber 110. While FIG. 2I illustrates three batch processing chambers 201 mounted in positions 114A-C, this configuration is not intended to limit the scope of the present invention since the number of position on the transfer chamber and the position or number of batch processing chambers are not intended to limit the various aspects of the invention described herein. This configuration may be desirable to improve hardware integration aspects of the design of the system, reduce system complexity and/or reduce system cost. The batch processing chambers 201 mounted in one of the positions 114A-C may be adapted to perform any number of processes, such as, ALD, CVD, rapid thermal processing (RTP), etching and/or cool down.

Referring to FIG. 2I, an optional front-end environment 104 is positioned so that it is in selective communication with a pair of load lock chambers 106 (described above). The factory interface robot 108, which is disposed in the front-end environment 104, is capable of linear, rotational, and vertical movement to shuttle substrates between the load locks 106 and a plurality of pods 105 which are mounted on the front-end environment 104. A robot 113 is centrally disposed in the transfer chamber 110 to transfer substrates under vacuum from the load locks 106 to one of the various processing chambers mounted in positions 114A-C. The robot 113 generally contains a blade assembly 113A, arm assemblies 113B which are attached to the robot drive assembly 113C. The robot 113 is adapted to transfer the substrate “W” to the various processing chambers by use of commands sent from the system controller 102.

In one embodiment, the cluster tool 100 illustrated in FIG. 2I may be adapted to process substrates at a pressure at or close to atmospheric pressure (e.g., 760 Torr) and thus no load locks 106A-B are required as an intermediate chamber between the factory interface and the transfer chamber 110. The transfer chamber 110 may be continually purged with an inert gas to minimize the partial pressure of oxygen, water, and/or other contaminants in the transfer chamber 110 and the batch processing chambers 201 that may be mounted in positions 114A-C. A plurality of slit valves (not shown) can be added to the transfer chamber 110 to isolate the each position from the other positions, so that each chamber may be separately evacuated to perform a vacuum process during the processing sequence.

The system controller 102 is generally designed to facilitate the control and automation of the overall system and typically may includes a central processing unit (CPU) (not shown), memory (not shown), and support circuits (or I/O) (not shown). The CPU may be one of any form of computer processors that are used in industrial settings for controlling various system functions, chamber processes and support hardware (e.g., detectors, robots, motors, gas sources hardware, etc.) and monitor the system and chamber processes (e.g., chamber temperature, process sequence throughput, chamber process time, I/O signals, etc.). The memory is connected to the CPU, and may be one or more of a readily available memory, such as random access memory (RAM), read only memory (ROM), floppy disk, hard disk, or any other form of digital storage, local or remote. Software instructions and data can be coded and stored within the memory for instructing the CPU. The support circuits are also connected to the CPU for supporting the processor in a conventional manner. The support circuits may include cache, power supplies, clock circuits, input/output circuitry, subsystems, and the like. A program (or computer instructions) readable by the controller 102 determines which tasks are performable on a substrate. Preferably, the program is software readable by the controller 102 that includes code to perform tasks relating to monitoring and execution of the processing sequence tasks and various chamber process recipe steps.

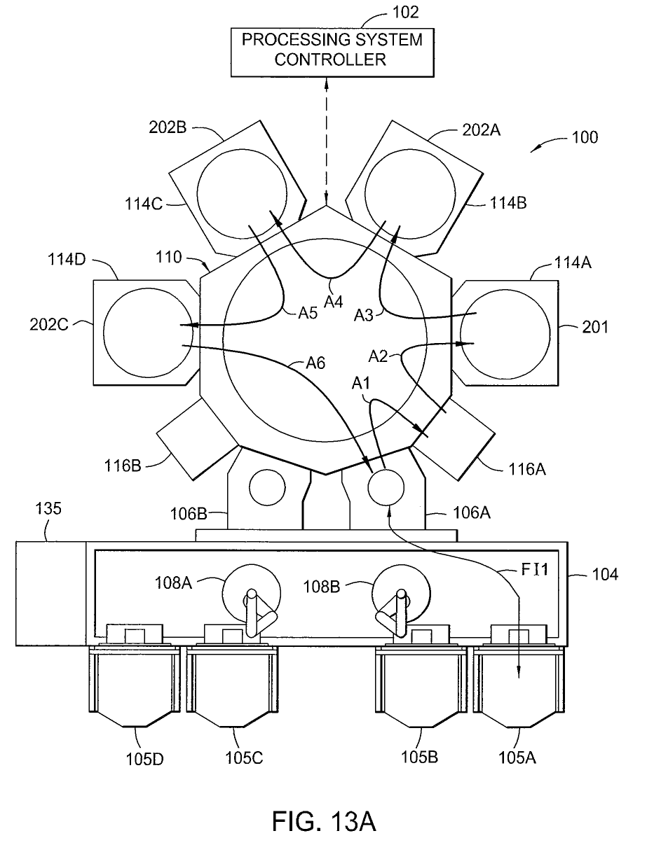

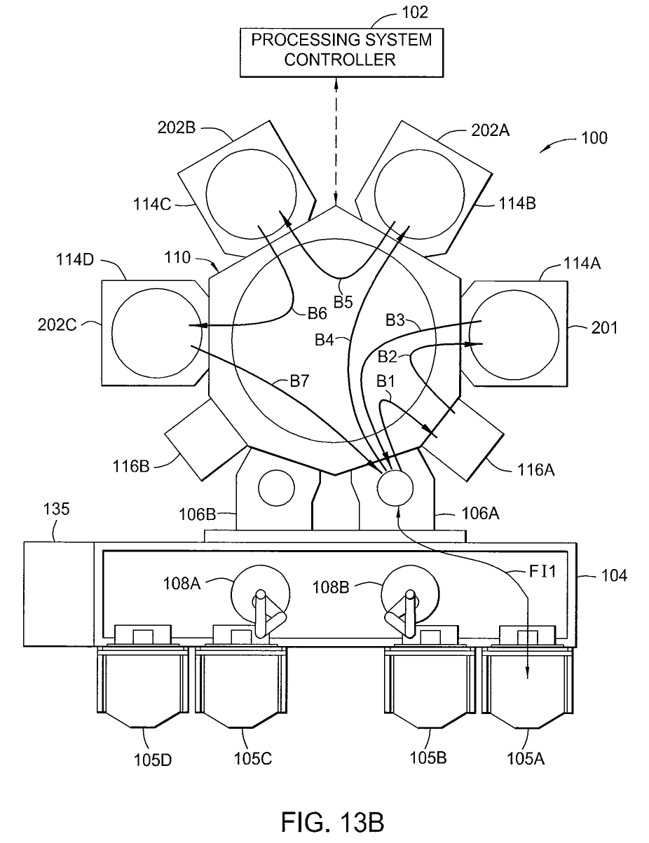

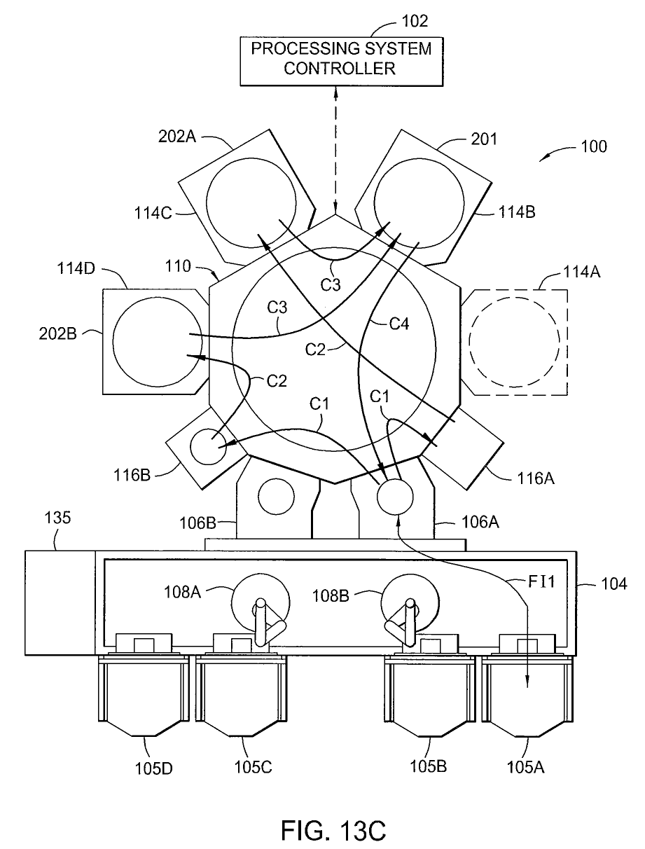

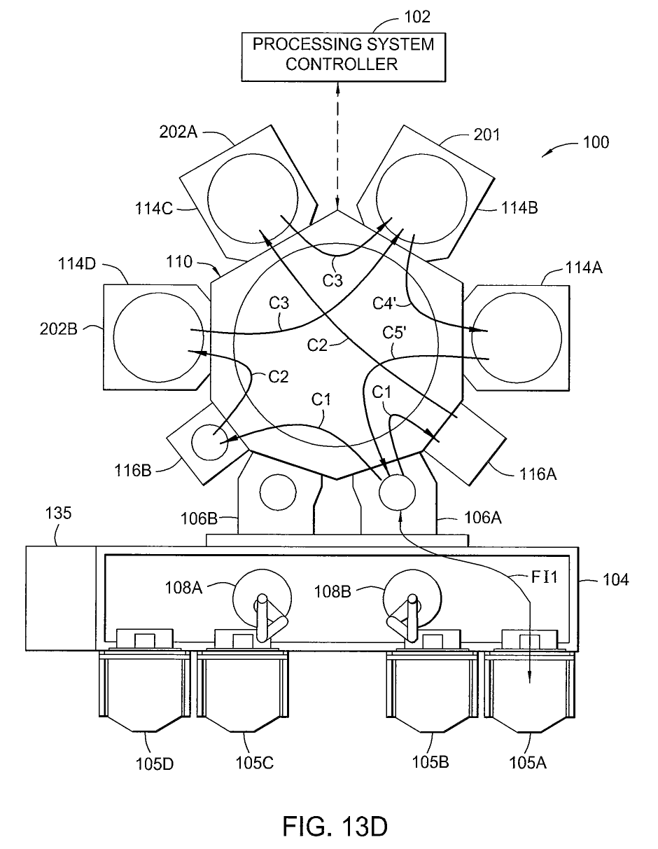

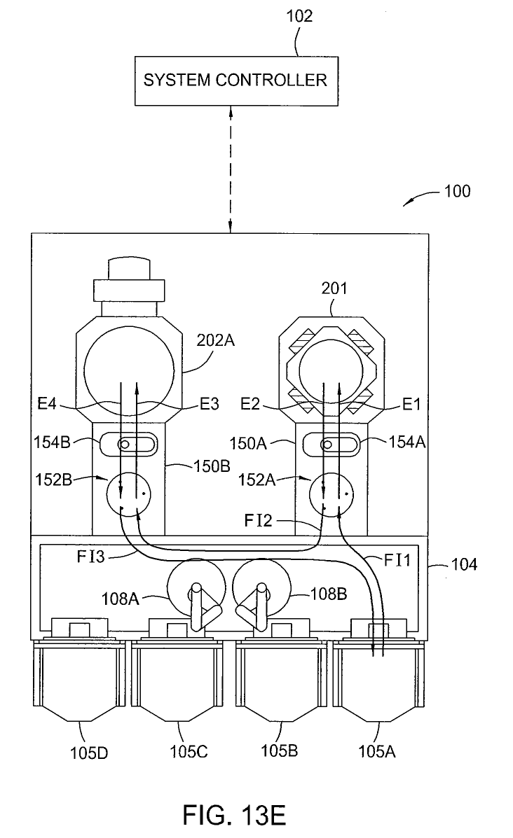

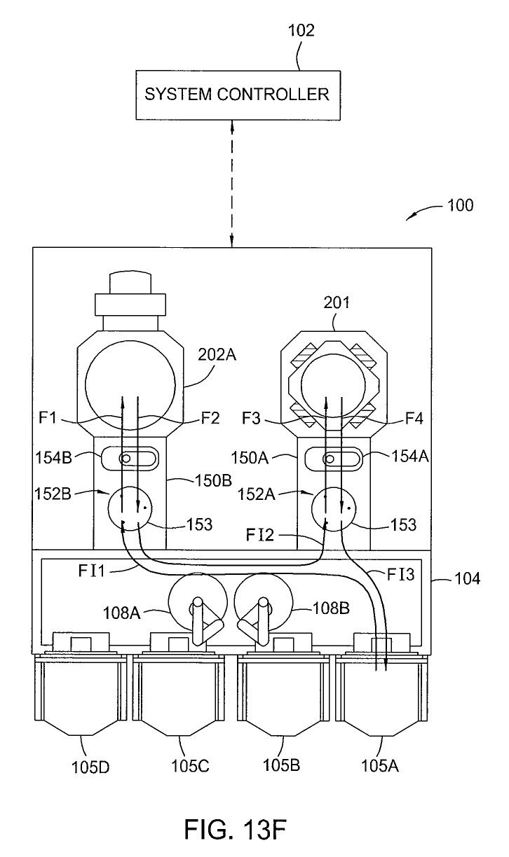

In one embodiment, the system controller 102 is adapted to monitor and control the queue time of the substrates processed in the cluster tool 100. Minimizing the queue time after a substrate is processed in a first processing chamber (e.g., single substrate processing chamber 202A or batch processing chamber 201) and before it is processed in the next processing chamber, will help to control and minimize the effect of the exposure to the contamination sources on device performance. This embodiment may be especially advantageous when used in conjunction with the various embodiments illustrated and described in FIGS. 13E-F. In one aspect of the invention the system controller is adapted to control the batch size (e.g., lot size) processed in the batch processing chamber 201 to minimize the time that the last substrate in the batch has to wait before it is processed in the next process chamber. In another aspect of the invention the controller 102 controls the timing of when a process recipe step is started or ended to optimize the system throughput and reduce any queue time issues. For example, the timing of when a single substrate processing chamber 202 starts processing a substrate is controlled to minimize the time the substrate has to wait after the process has been completed to the time when the next processing chamber, such as the batch processing chamber 201 is ready to accept the processed substrate.

### Batch Chamber Hardware

The batch processing chamber 201, while primarily described below as an ALD or CVD chamber, may also be adapted to perform a batch plasma oxidation process, or other semiconductor processes that are conducive to being performed on multiple substrates at one time to achieve some desired processing result.

In one embodiment, the batch processing chamber 201 is a CVD chamber which is configured to deposit a metal layer, a semiconductor layer and/or a dielectric material layer. Examples of hardware and methods used to perform such processes is further described in U.S. patent application Ser. No. 6,352,593, entitled “Mini-batch Process Chamber” filed Aug. 11, 1997, and U.S. patent application Ser. No. 10/216,079, entitled “High Rate Deposition At Low Pressure In A Small Batch Reactor” filed Aug. 9, 2002, which are hereby incorporated by reference in their entireties. In another embodiment, the batch processing chamber 201 is an ALD chamber which is configured to deposit a metal layer, a semiconductor layer and/or a dielectric material layer.

FIG. 3, is a side view of an exemplary batch processing chamber 201. The batch processing chamber 201 includes a vacuum chamber 22 having a process volume 22a, or substrate processing region, and buffer volume 22b, or substrate buffer region. Generally, the buffer volume 22b is used for inserting substrates into and removing substrates from batch processing chamber 201 and process volume 22a is used as the processing chamber. Process volume 22a, or substrate processing region, and buffer volume 22b, or substrate buffer region, are welded together or bolted together and vacuum sealed using an sealing structure 24 or other conventional means. In one embodiment, the orientation of the process volume 22a and the buffer volume 22b and all the associated hardware, can be interchanged, such that, the buffer volume 22b is positioned above, or vertically adjacent to, the processing volume 22a (not shown). A vertically adjacent orientation, where the processing volume 22a is positioned above the buffer volume 22b, or the buffer volume 22b is positioned above the processing volume 22a, may be advantageous, since it reduces the cluster tool footprint versus a horizontally adjacent orientation, which is often a very important design consideration for semiconductor manufacturing tools. The orientation of the process volume 22a and the buffer volume 22b as illustrated and described herein is not intended to be limiting as to the scope of the invention.

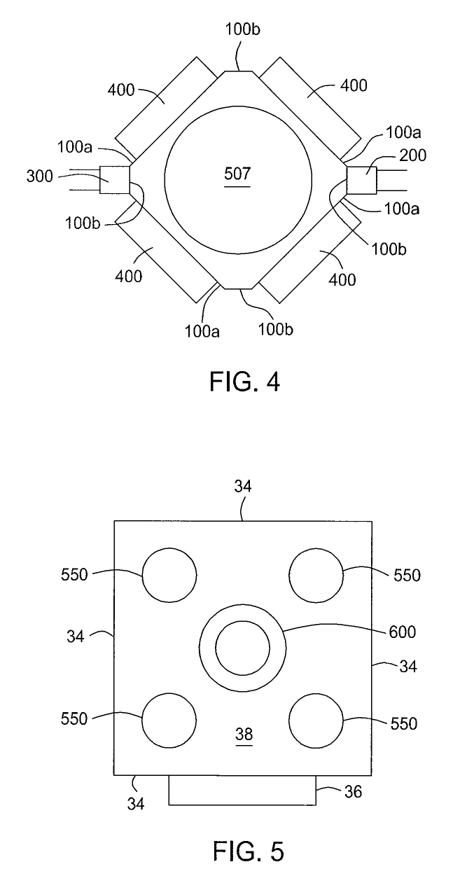

FIG. 4, is a top view of the batch processing chamber 201 illustrated in FIG. 3. The process volume 22a, as shown in FIG. 4, has four side walls 100a and four side walls 100b all of which may be temperature controlled via a recirculating a heat exchanging fluid. A gas injection manifold assembly 200 and an exhaust manifold assembly 300 are attached to opposite walls 100b, and are discussed in more detail below. A multiple zone heating structure 400 is attached to each of the four side walls 100a. A liquid-cooled top plate 32 (FIG. 3) made of, for instance, aluminum is vacuum sealed via an O-ring or other means (not shown) to side walls 100a and 100b. A multiple zone heating structure 507 is positioned above top plate 32 (FIG. 3).

Referring now to FIGS. 3 and 5, buffer volume 22b includes four side walls 34. Attached to one of these side walls is a slit valve opening 36 through which the arm of the robot 113 may insert (remove) a substrate into (from) buffer volume 22b in a well known manner. The slit valve opening 36 is vacuum sealed to one of the side walls 34 in a well known manner using for instance an O-ring (not shown). The slit valve opening 36 is designed so that it can be attached to any of the chamber mounting surface 111A-D (see FIG. 2A) of the transfer chamber 110. Typically, the transfer chamber 110 houses slit valves (not shown) which isolate the process chambers mounted in the positions 114A-D during processing from the transfer chamber 110.

A bottom plate 38 is attached to and vacuum sealed to each of side walls 34 using an O-ring (not shown). A plurality of heating structures 550 similar to heating structure 507 are attached to an exterior surface of bottom plate 38. The amount of heat delivered from the heating structures 550 is controlled by the system controller 102. A lift and rotation mechanism 600 which is positioned in the middle of bottom plate 38 and by use of commands from the system controller 102 is able to lift and rotate the a cassette 46 and its associated parts. In one embodiment, the heating structure 550 components are removed on the bottom plate 38 to reduce cost and batch chamber complexity.

Referring now to FIG. 6, which illustrates a batch processing chamber 201 in a loading/unloading condition. In this position the robot 113 can load the substrates into one of the plurality of slots in the cassette 46. The robot 113 has access to the cassette 46 through a slit valve opening 36 (not shown in FIG. 6). Cassette 46 may be constructed of any suitable high temperature material such as, for instance, quartz, silicon carbide, or graphite, depending upon desired process characteristics. FIG. 6 illustrates a cassette 46 which can hold up to nine substrates “W”, but other embodiments of the cassette 46 may be adapted to hold a greater or lesser number of substrates. Preferably the cassette 46 will hold at least 25 substrates.

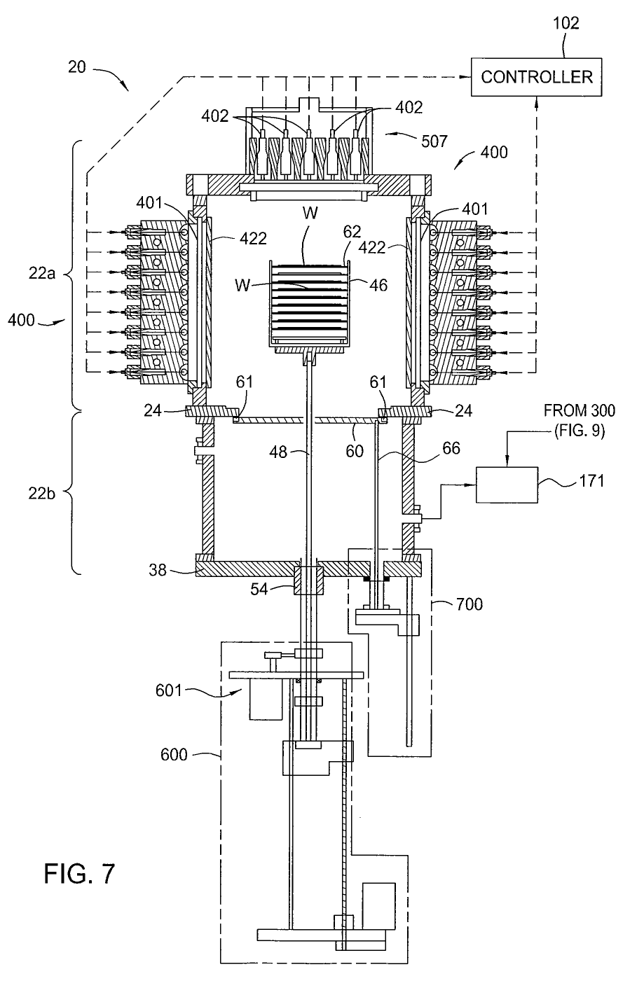

A circular seal plate 60 is positioned immediately below cassette 46 and is intended to seal off, or minimize process gas leakage into, the buffer volume 22b from the process volume 22a of the batch processing chamber 201 when the ALD or CVD processes are to be preformed on the substrates mounted in the cassette 46. The seal plate 60 is constructed from a suitable high temperature material such as for instance graphite or silicon carbide and has nested into a groove around the outer periphery of its top surface a quartz ring 61. Seal plate 60 is supported by three lift rods 66, and their associated lift mechanisms 700, and is constructed from a suitable high temperature material (only one lift rod 66 is shown for simplicity). Referring now to FIGS. 6 and 7, lift mechanism 700 vacuum sealed to the bottom plate 38 by use of seal 54 (e.g., elastomeric seal, ferrofluidic seal) and is adapted to allow the seal plate 60 to move independently of the cassette 46. The lift mechanism 700, which raises and lowers the seal plate 60 can be actuated by hydraulic, pneumatic or electrical motor/lead screw mechanical actuator(s) all well known in the art.

After each of substrates “W” are loaded into a slot in cassette 46, the blade assembly 113A (FIG. 2A) is retracted and cassette 46 is elevated to a predetermined distance by use of the system controller 102 so as to allow the robot 113′s blade assembly 113A to load the next substrate into the next slot of cassette 46. This process is repeated until the desired number of substrates “W” is loaded into cassette 46. The number of substrates loaded into the cassette may be controlled or varied as the substrate batch size varies or it may be varied to balance the system throughput such that the last wafers processed in the batch processing chamber are not idle for a period of time exceeding an acceptable queue time. The system controller 102 is used to determine the optimum batch size to minimize the wait time and balance the system throughput based on programmed process sequence information, the calculated timing based on actual or prior experimental throughput information, or other user or system inputs. After slit valve opening 36 is closed, cassette 46 and substrates “W” are then elevated from the buffer volume 22b to a processing position within process volume 22a, as illustrated in FIG. 7.

As cassette 46 is elevated by the lift and rotation mechanism 600 into process volume 22a, quartz ring 61 of seal plate 60 is moved into intimate contact with an inner lip of sealing structure 24 by use of the lift mechanism 700, thereby stopping seal plate 60 in the position shown in FIG. 7. When quartz ring 61 is in intimate contact with sealing structure 24, seal plate 60 provides an almost complete seal between process volume 22a and buffer volume 22b portion of chamber 22, where process volume 22a becomes the processing area of the reaction chamber 20 in which layers of suitable material may be formed on substrates “W”. By injecting a relatively small flow of inert gas such as argon or helium into the buffer volume 22b, such inert gas must travel through the small gap between the hole in seal plate 60 and the shaft 48 on its way to being exhausted in process volume 22a. This inert gas flow serves to greatly minimize the amount of reactive gasses the can enter the buffer volume 22b from the process volume 22a thereby effectively eliminating excessive and unwanted vapor deposition upon the heated parts in buffer volume 22b. In addition, such containment of the often expensive reactive gases within the process or process volume 22a results in more efficient use of these gases. Further, this containment results in an effective reduction of the reaction chamber's volume thereby reducing the residence time (the average time it takes a molecule of gas to travel from the point of injection to its being exhausted on the opposite side of the chamber) of the reactive gases. For a number of typical ALD and CVD processes, excessive residence time can lead to unwanted chemical reactions that may generate sub-species which can be incorporated into the growing ALD or CVD film. Seal plate 60 provides effective thermal isolation between process volume 22a and buffer volume 22b. In addition, seal plate 60 also serves as a thermal diffuser for heat energy emitted from heating structure 550 and, in this manner, acts as an intermediate heat source for substrates “W”. Further, seal plate 60 may provide an effective containment to improve any in situ plasma cleaning process completed in the batch processing chamber 201 during maintenance activities.

In one aspect of the invention, as shown in FIGS. 6-7, the multiple zone heating structure 507 contains an array of halogen lamps 402 which radiate energy towards the substrates mounted in a cassette 46. In another embodiment, the multiple zone heating structure 507 contains one or more resistive heating elements (not shown), in place of the halogen lamps 402, to transfer heat to the substrates retained in the cassette 46.

In one embodiment of the batch processing chamber 201, a vacuum pump system 171 (FIGS. 2G-2H) is used to evacuate the buffer volume 22b and/or process volume 22a prior to performing the desired chamber process. In one aspect, when the batch processing chamber 201 is in transferable communication with a transfer chamber 110, which is typically is maintained at a vacuum pressure, the buffer volume 22b and process volume 22a will generally always be maintained in a vacuum pressure to allow rapid transfer of the substrates to the batch processing chamber(s) 201. It should be noted that in one aspect of the invention, when the batch processing chamber 201 is in transferable communication with a front-end environment 104 that is at atmospheric pressure, the buffer volume 22b will need to be pumped down by use of the vacuum pump system 171 prior to processing, and then vented by conventional means after processing to allow the substrates to be transfer between the batch processing chamber 201 and the front-end environment 104, or vice versa. The vacuum pump system 171 may be attached to a single processing chamber or multiple processing chambers positioned in the cluster tool 100. The vacuum pump system 171 may contain one or more vacuum pumps, such as a turbo pump, rough pump, and/or Roots Blower™ that are used to achieve the desired chamber processing pressures (e.g., ˜50 mTorr-˜10 Torr).

Referring to FIG. 2H, in one embodiment of the batch process chamber 201, a shutter assembly 180 is used to isolate the buffer volume 22b and the process volume 22a to allow the process volume 22a to be maintained at a vacuum state while the buffer volume 22b is vented so that substrates can be loaded or removed from the cassette 46, or other maintenance activities can be performed on the buffer volume 22b components. The shutter assembly 180 generally contains a shutter door 181, shutter storage region 182, a sealing member 183 (e.g., o-ring) mounted on the shutter door 181, and a shutter actuator (not shown). The shutter actuator is adapted to position the shutter door 181 over the opening in the sealing structure 24 to isolate the buffer volume 22b and the process volume 22a so that the process volume 22a can be maintained at a vacuum pressure by use of the vacuum pump system 171, while the buffer volume 22b is vented to atmospheric pressure. The shutter actuator is also generally adapted to move and position the shutter door 181 out of the way of the cassette 46 and into the shutter storage region 182 during the insertion of the cassette 46 into the process volume 22a prior to processing.

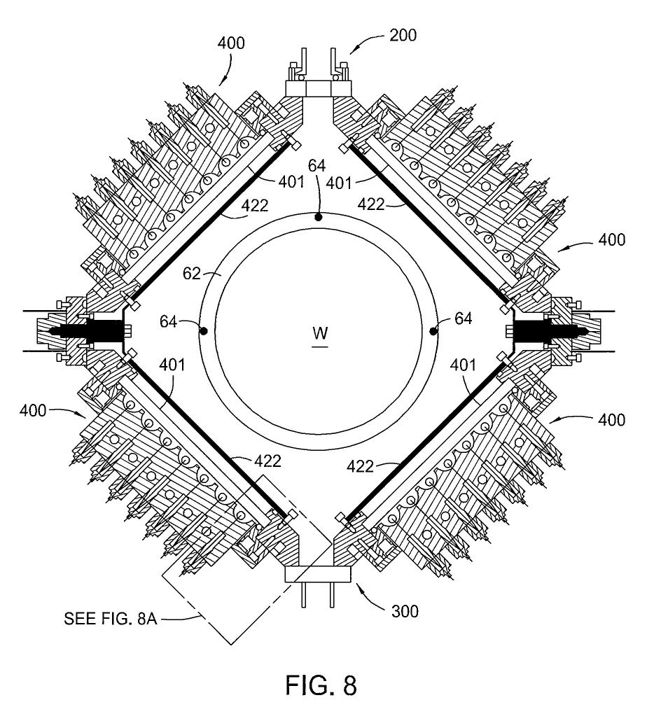

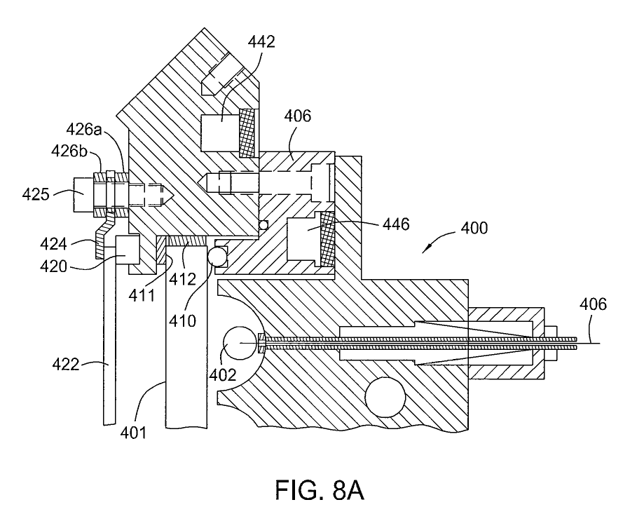

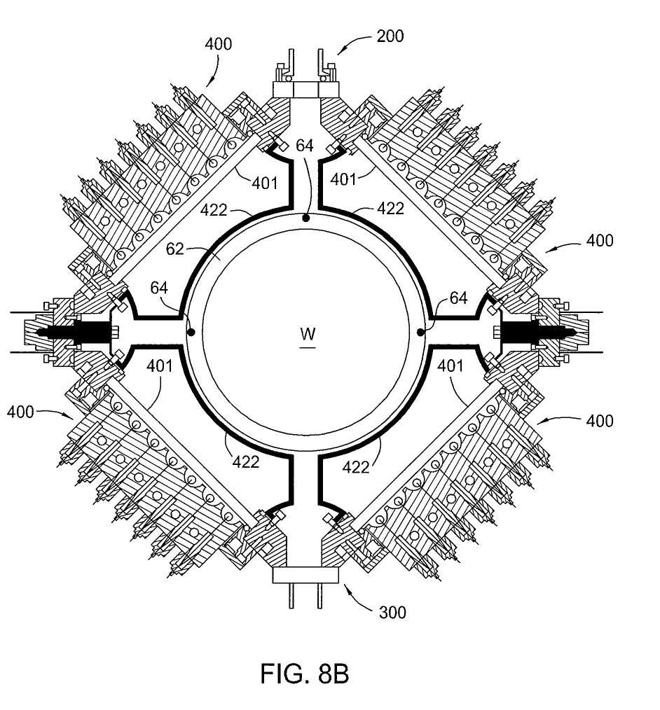

Referring to FIGS. 8 and 8A, a heating structure 400 is mounted on an exterior surface of each of side walls 100a. The heating structure 400 contains a plurality of halogen lamps 402 which are used to provide energy to the substrates “W” in the process volume 22a of the batch processing chamber 201 through a quartz window 401. In one embodiment, the substrates “W” and cassette 46 are heated to an appropriate temperature indirectly by thermal shield plate 422, which are heated by halogen lamps 402 through quartz window 401. Alternative heating methods instead of lamps such as resistive heaters may be used. An O-ring type gasket 410 (constructed of a suitable material such as, for instance, viton, silicon rubber or cal-rez graphite fiber) and strips 412 and gasket 411 of a similar suitable material are provided between quartz window 401 and side wall 100a and clamp 406 to ensure that the window 401 does not come in direct contact with either the side wall 100a or the clamp 406 to prevent the undue stress that would cause an implosion if the window 401 were in direct contact with the temperature controlled side wall 100a or the clamp 406 when the window 401 is hot and the chamber 22 is under vacuum. Thermal shield plates 422 are added to the process volume 22a of the chamber to diffuse the energy emitted from the heating structures 400 to allow a more uniform distribution of heat energy to be provided to substrate “W”. In one embodiment, the distribution of heat energy is further optimized by rotating the cassette 46 during processing using a rotation motor 601 found in the lift and rotation mechanism 600. The rotation speed of the cassette may vary from about 0 to about 10 revolutions per minute (rpm), but preferably between about 1 rpm and 5 rpm. The thermal shield plate 422 and insulating quartz strip 420 are made of a suitable high temperature material such as, for instance, graphite or silicon carbide is secured to side wall 100a by a plurality of retaining clamps 424 which are made from suitable high temperature material such as titanium. The clamps 424 are mounted on the side wall 100a using bolts 425 and washers 426A-B.

In one embodiment, one or more heat exchanging devices are placed in communication with the side walls 100a and 100b, the top plate 32 and/or the bottom plate 38 to control the batch chamber's wall temperature. The one or more heat exchanging devices can be used to control the batch chamber's wall temperature to limit the amount of condensation of unwanted deposition materials and/or deposition process by-products during processing, and/or also protects the quartz windows 401 from cracking due to thermal gradients created during processing. In one embodiment, as shown in FIGS. 8 and 8A, the heat exchanging device consists of milled channels 442 and 446 formed in side walls 100a-b and clamp 406, which are temperature controlled by use of a heat exchanging fluid that is continually flowing through the milled channels 442 and 446. A fluid temperature controller (not shown) is adapted to control the heat exchanging fluid and thus the side walls 100a-b and clamp 406 temperature. The heat exchanging fluid may be, for example, a perfluoropolyether (e.g., Galden®) that is heated to a temperature between about 30° C. and about 300° C. The heat exchanging fluid may also be chilled water delivered at a desired temperature between about 15° C. to 95° C. The heat exchanging fluid may also be a temperature controlled gas, such as, argon or nitrogen.

To achieve uniform and desirable process results on all substrates “W” processed in the process volume 22a requires that every point on all of the substrates “W” in the batch attain the same set point temperature plus or minus only about 1 degrees Celsius. The temperature set point and uniformity is monitored and controlled by use of one or more thermal sensors (e.g., optical pyrometers, thermocouples, etc.) positioned to measure the temperature of various areas of the cassette, two or more halogen lamps 402 (FIG. 7) that are grouped into multiple zones, and a system controller 102 which monitors the temperatures and controls and adjusts the power to each of the zones to achieve a uniform temperature along the length of the cassette 46. In one embodiment, a row of the halogen lamps 402 or multiple rows of halogen lamps 402 can be controlled by the system controller 102 to assure that the temperature is uniform from substrate to substrate in the cassette 46. In one embodiment the lamps are grouped by regions, where one or more lamps in a row (horizontal) and one or more lamps in a column (vertical) are controlled together to adjust for variability in temperature in a region of the process volume 22a. Embodiments of the multizone control of the halogen lamps 402 and heating structure 400 hardware are further described in U.S. patent application Ser. No. 10/216,079, entitled “High Rate Deposition At Low Pressure In A Small Batch Reactor” filed Aug. 9, 2002 which are incorporated herein by reference.

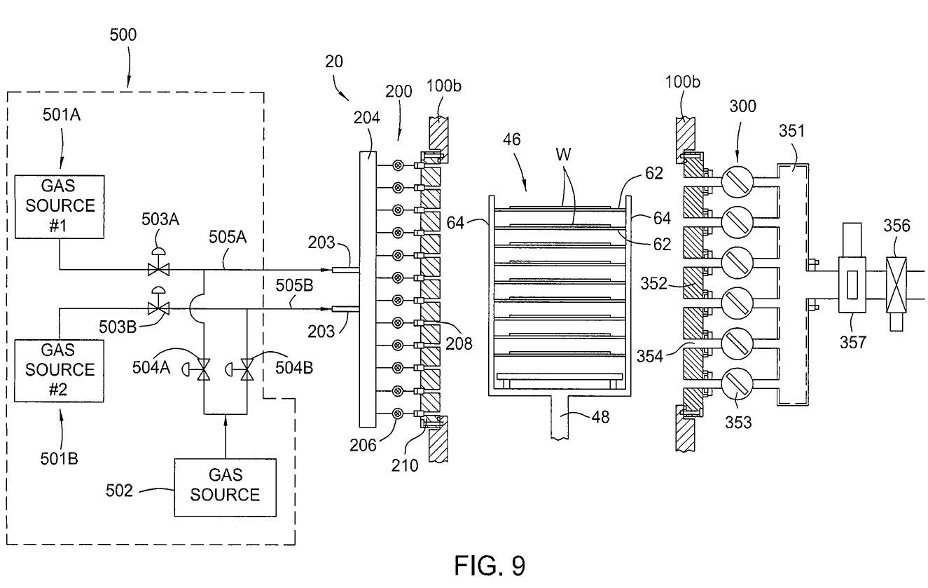

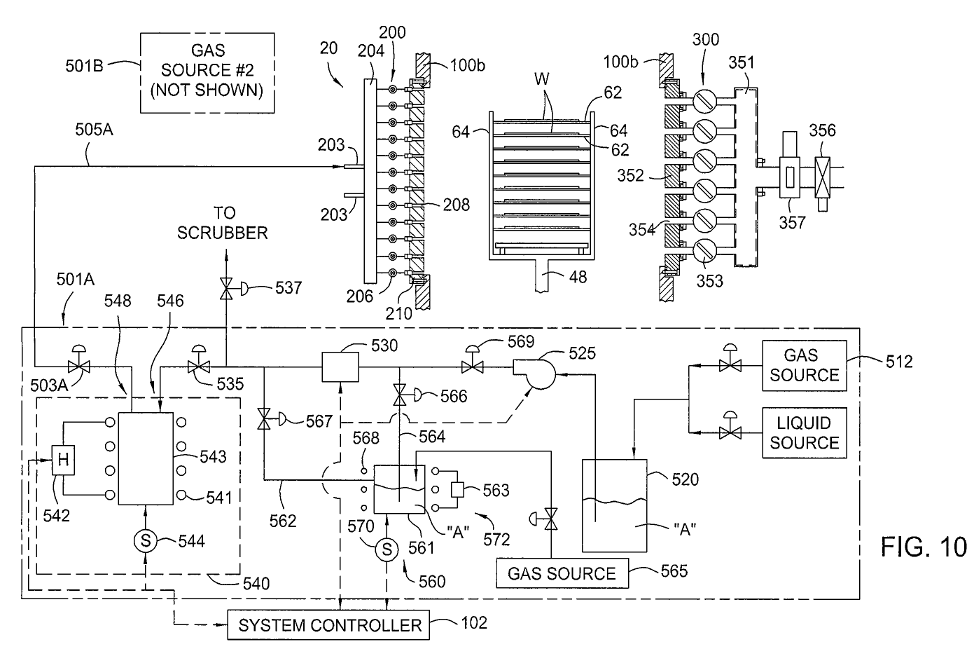

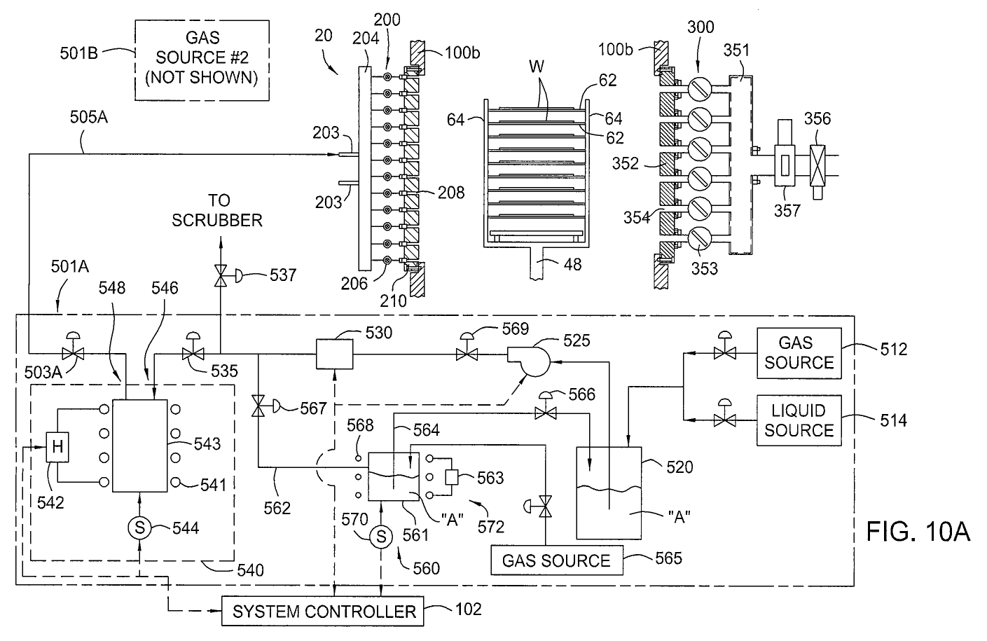

In one embodiment, as shown in FIGS. 9-10, the cassette 46 contains a susceptor 62 and rods 64, which support the substrate. In this embodiment each substrate “W” may rest directly on a susceptor 62, or the substrate may be nested in a cavity within a susceptor 62 (not shown), or it may be suspended between two susceptors 62 (not shown), such as on three or more pins attached to the surface of a susceptor 62. In this embodiment the susceptors 62 are sized such that it is larger than the diameter of the substrate “W” so that it can absorb the radiant energy delivered from the heating structure 400 (not shown in FIG. 9 or 10) and it will tend to preheat the process gas before it reaches the substrate edge.

In one embodiment, the process temperature of the substrates mounted in the cassette 46 is varied during different phases of the process recipe by varying the amount of energy transferred to the substrates from the heating structures 400. In this configuration it may be necessary to minimize the thermal mass of the cassette 46 to allow the substrate temperature to be adjusted rapidly during the process. Therefore, in one aspect of the invention the mass and size of the susceptors 62 and rods 64 may be minimized to allow for the process temperature to be adjusted rapidly and substrate thermal uniformity to be achieved.

Embodiments of the heating structure 400 hardware are further described in U.S. patent application Ser. No. 6,352,593, entitled “Mini-batch Process Chamber” filed Aug. 11, 1997, and U.S. patent application Ser. No. 10/216,079, entitled “High Rate Deposition At Low Pressure In A Small Batch Reactor” filed Aug. 9, 2002 which are incorporated herein by reference.

### Gas Delivery System

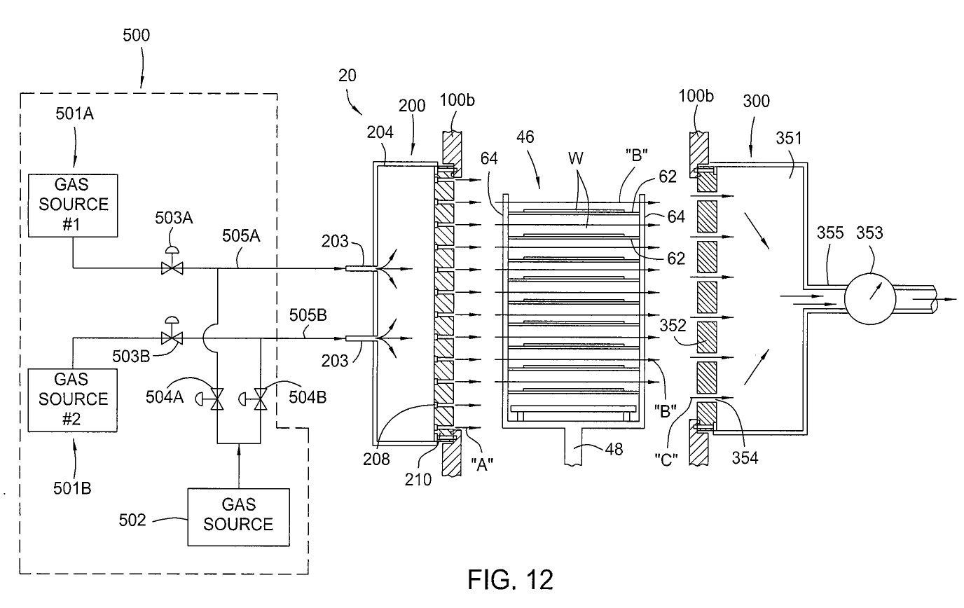

Referring now to FIGS. 9-10 and 12, process gases to be used in depositing layers on substrates “W” are provided to a gas injection manifold assembly 200, which generally may include a gas delivery module 500, one or more inlet ducts 203, a mixing chamber 204 and an injection plate 210. In one embodiment, the injection plate 210 is vacuum sealed to one of side walls 100b via an O-ring (not shown). After the process gasses are mixed together in mixing chamber 204 the gases are provided to ports 208 formed in injection plate 210, and then the process gasses then flow through the ports 208 and into the process volume 22a. In one embodiment the ports 208 are formed so that they can restrict and evenly redistribute the incoming gas(es) (e.g., a showerhead) so that the gas flow entering the process volume 22a of the batch processing chamber 201 is uniform (see FIG. 12). In one embodiment, as shown in FIG. 9, on or more gas flow control devices 206 are added between the mixing chamber 204 and the ports 208, to provide precise control over the amount of process gas flow provided into process volume 22a of the batch processing chamber 201. In one embodiment, the gas flow control devices 206 may be a mechanical butterfly valve or needle valve, or other equivalent device that can control the flow of the process gas. In another aspect of the invention the injection plate 210 is temperature controlled by use of a temperature controlled heat exchanging fluid that flows through milled channels (not shown) in the injection plate 210 or with the use of resistive heating elements embedded into the housing of the injector. While FIGS. 9, 10 and 12 illustrate a single mixing chamber 204 and injection plate 210 in communication with two or more process gas sources 501 and the process volume 22a, embodiments of the injection manifold assembly 200 may include two or more isolated mixing chambers 204 and injection plates 210, which each inject various process gasses (e.g., precursors, oxygen containing gas(es), carrier gasses, etc.) into the process volume 22a. In one aspect of the invention the two or more isolated mixing chambers 204 and injection plates 210 are adjacent to each other and all mounted on the same side wall 100b. For example, in one configuration the injection manifold assembly 200 may include three separate mixing chambers 204 and injection plates 210 which are intended to separately deliver a hafnium precursor (e.g., TDMAH), a carrier gas (e.g., argon), and an oxygen containing gas into the process volume 22a to form a hafnium oxide film. This configuration thus minimizes the interaction of incompatible process gases and may reduce the need to purge the injection manifold assembly 200 and the process volume 22a after flowing a first processing gas during processing.

The gas delivery module 500 will generally contain an inert gas source 502 and one or more process gas sources 501, which can deliver various process gases necessary to complete an ALD, CVD, or other substrate processing steps. FIG. 9 illustrates one embodiment that contains two process gas sources 501A-B. An inert gas source 502 may also be used to purge the inlet lines 505A-B and in some embodiments may act as a carrier gas to deliver the process gasses from the gas sources 501A-B. In one embodiment, the gas source 502 delivers an oxygen containing gas to the substrates. In another embodiment, the gas source 502 is an ozone generating source which can be delivered to the substrates.

The gas flow distribution across the surface of the substrates is vital to the formation of uniform layers upon substrates “W” processed in the batch processing chamber 201, especially for high rate CVD processes that are dominated by mass transport limited reactions and for ALD processes where rapid surface saturation is required for reaction rate limited deposition. ALD or “cyclical deposition” as used herein refers to the sequential introduction of one or more reactive compounds to deposit a layer of material on a substrate surface. The reactive compounds may also be introduced into a processing area of a processing chamber in an alternating fashion. Usually, the injection of the each reactive compound into the process region is separated by a time delay to allow each compound to adhere and/or react on the substrate surface.

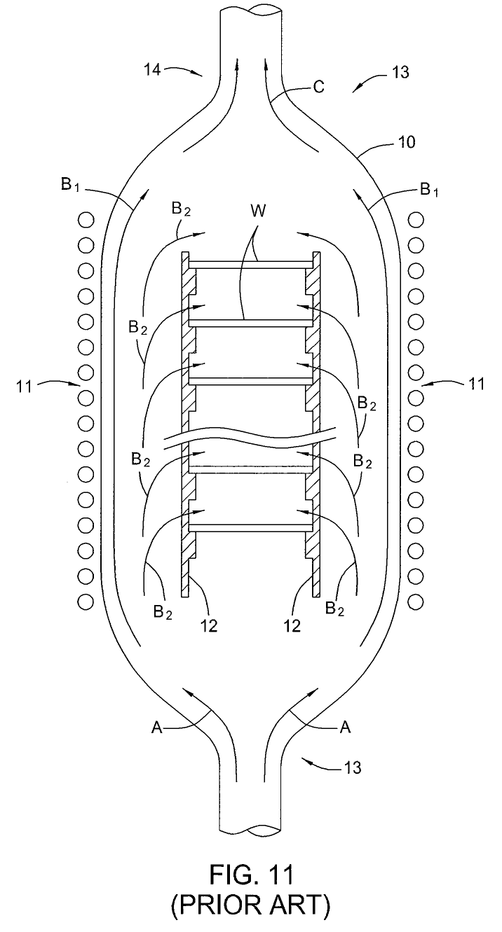

FIG. 11 illustrates a cross-sectional view of a prior art vertical diffusion furnace 13 (or VDF). In general a vertical diffusion furnace 13 will contain a chamber wall 10, a heating source 11, a substrate support 12 that holds the substrates “W”, an inlet 13 and an outlet 14. Before performing a processing step on the substrates “W”, each substrate is loaded into the substrate support 12 through an access port (not shown) by use of a robot (not shown) and the chamber is evacuated or purged with an inert gas. During processing a process gas is injected into the inlet 13 (see item “A”) which then flows around the substrate support 12 (see item “B₁”) and out the outlet 14 (see item “C”). In this configuration the precursor diffuses across the edge of the substrate towards the center of the substrate (see item “B₂”). The vertical diffusion furnace 13 deposition process is thus dependent on the diffusion, or migration, of the processing gas across the surface of the substrate surface to achieve uniform deposition coverage. Although, relying on a diffusion type process to form a film that has desirable properties can be problematic for two main reasons. The first problem arises since the edge of the substrate is exposed to a higher concentration of the process gas than the center which can lead to variations in the deposited film thickness and/or contamination due to the presence of unreacted excess precursor on the surface of the deposited film at the edge of the substrate. Second, the deposition can vary spatially or as a function of time since the diffusion process is process gas temperature dependent process and is also a time dependent process which can vary from position to position in the substrate support.

Therefore, in an effort to overcome the short comings of the prior art, embodiments of the invention inject the process gas(es) into the process volume 22a and across the substrates “W”, which is a convective type process, since convective type processes do not suffer from the problems associated with a diffusion dependent process. A convective type process is beneficial since interaction of the process gas and the substrate surface can be controlled and not left to chance or is not based on factors that are hard to control. FIG. 12 illustrates one embodiment in which the process gas is injected through the ports 208 in the injection plate 210, across the plurality of substrates “W”, then through the exhaust ports 354 in the exhaust plate 352, and then out to an exhaust pump (not shown) and scrubber (not shown). In one aspect of the invention, as illustrated in FIG. 12, the process gas is injected in a direction that is generally parallel to the processing surface of the substrate (e.g., surface containing semiconductor devices). A parallel process gas flow allows for the rapid saturation of the processing surface(s) of the substrate and thus reduces the processing time. In another aspect of the invention, the process gas flow is evenly distributed across all of the substrates retained in the cassette 46 by use of the flow distributing injection plate 210.

In another aspect of the invention the exhaust manifold assembly 300 is positioned in an orientation that is substantially opposing the injection manifold assembly 200. In this configuration the flow path and thus exposure of the substrates to the injected process gases is uniformly distributed, since the flow path of the process gasses remains substantially parallel to the substrate surface. In one embodiment, there are two or more pairs of opposing exhaust manifold assemblies 300 and injection manifold assemblies 200 that are spaced peripherally around the cassette 46 (not shown), where each pair can be used separately or in unison with other pairs.

In other aspects of the invention it may be beneficial to include one or more exhaust manifold assemblies 300 that are at orientations that are not opposing the injection manifold assembly 200, or one or more injection manifold assemblies 200 that are at orientations that are not opposing one or more exhaust manifold assemblies 300. Generally, in the non-opposing configurations, the ports 208 in the injection plate 210 have corresponding exhaust ports 354 in the exhaust plate 352 that are substantially in the same plane with each other to allow for a substantially parallel flow path of the process gas across the substrate surface.

The process of injecting the process gas into the process volume 22a from a higher pressure process gas source 501, imparts a velocity to the process gas which promotes a convective type mass transport to the substrate surface. The process gas velocity and the total mass of the gas injected are just a few of the process variables that can be varied to affect the deposited film properties. The gas velocity across each substrate “W” depends on the gap between the substrate “W” and the susceptors 62 (one above and below the substrate), as well as on the gap between the outside edge of the susceptors 62 and the thermal shield 422 (FIGS. 8 and 8B). The different gaps can each have an effect on the repeatability and uniformity of the deposited film since it will directly affect the gas flow across the surface of the substrate. In general, the gap between a substrate “W” and its corresponding upper susceptor 62 is preferably in the range of about 0.2 to about 1.5 inches. The gap between susceptors 62 and thermal shield 422, the gap between susceptors 62 and the injection assembly 200, and/or the gap between susceptors 62 and the exhaust manifold assembly 300, is preferably less than or equal to the gap between two subsequent susceptors 62. Preferably the gap is between the thermal shield and the susceptor 62 is between about 0.05 and about 1.0 inches. Minimizing the distance between the thermal shield plate 422 and susceptors 62 improves heat transfer to the susceptors. In one embodiment of the process volume 22a, the gap between a susceptor 62 and a thermal shield plate 422 may be decreased by using thermal shields that are semicircular and thus wrap around the susceptors 62. FIG. 8B illustrates an example of one embodiment of the process volume 22a having semicircular thermal shield plates 422.

As noted above the gas velocity across the substrates can vary as a function of the pressure drop of the process gas delivered into the process volume 22a. The velocity of the gas can thus be controlled by varying the process gas source 501 delivery pressure (e.g., the vessel 543 pressure (discussed below)), by controlling the process gas flow rate, and/or the process volume 22a processing pressure. For example, the vessel 543 pressure may be maintained at 5 Torr and the process volume 22a is pumped to <50 mT before the process gas is injected into the process volume 22a and thus there is a large pressure differential between the two volumes. In one embodiment, the process volume 22a pressure is varied during a process recipe step by controlling the process gas flow rate and/or the exhaust flow rate to thus vary the mass transport process to achieve improved process results.

To perform an ALD process a dose, or fixed mass, of the precursor is injected into the process volume 22a at a known pressure to control the growth of the deposited film. The initial high concentration of precursors upon injection of process gas into the processing area allows a rapid saturation of the substrate surface including the open sites on the substrate surface. If the high concentration of precursor is left in the chamber for too long, more than one layer of the precursor constituent will adhere to the surface of the substrate. For example, if too much of a hafnium containing precursor is adsorbed on the substrate surface, the resulting film will have an unacceptably high hafnium concentration. A controlled, gradual or stepped reduction in processing area pressure may help to maintain an even distribution of chemicals along the substrate surface while forcing the excess precursor and carrier gases out of the processing area. In one aspect of the invention, it may also be advantageous in one or more steps of the ALD process to purge the system with additional purge gas such as nitrogen or argon, while also controlling the process volume 22a pressure, to remove the excess precursor. A controlled, gradual reduction in the processing area pressure may also prevent a temperature decrease that is common with a rapid decrease in pressure. An example of an exemplary process includes filling a vessel 543 maintained at 100° C. and a pressure of 5 Torr with a process gas containing 100% TDMAH into the process volume 22a which is maintained at a chamber pressure of 8 Torr for 2 seconds and then 2 Torr for 3 seconds after the injection of the precursor.

To assure that a uniform ALD layer is formed on a substrate surface, various chamber processing techniques are used to control the precursor concentration in the process volume 22a during processing. In all of the ALD processes a fixed mass of precursor is dosed into the process volume 22a which is large enough to assure saturation of all of the surfaces in the process volume 22a so that a thin ALD layer can be formed on the substrate. The control of the saturation and evacuation of the process volume 22a, so that desirable deposited film properties can be achieved, is controlled by use of three main processing techniques or methods. The first ALD processing method, as noted above, requires that the dose of precursor be delivered while the process volume 22a is maintained at a single process pressure during the ALD process. After the mass of precursor is injected into the process volume 22a, a single processing pressure is maintained by varying the flow of a carrier gas (e.g., argon, helium, etc.) into the process volume 22a, and/or controlling the exhaust flow rate to an external vacuum pumping system (not shown). The exhaust flow rate can be controlled by restricting the exhaust flow to the external vacuum pump system by controlling the exhaust flow control devices 353 position (FIG. 12). The second ALD processing method, also noted above, basically entails injecting a mass of the precursor gas into the process volume 22a and then varying the process volume 22a pressure by controlling a carrier gas flow rate or the exhaust flow rate for the remaining part of the process. The second method thus allows the process pressure to be controlled at various different levels during the ALD process to assure an even distribution of chemicals and a desirable processing conditions are maintained during the different phases of the ALD deposition process. In a third ALD processing method, the mass of precursor is injected while the exhaust flow is halted for a period of time and then the exhaust flow is restarted. In this configuration the concentration of precursor gas in the chamber will remain unchanged after the initial dose of the precursor, until the exhaust flow rate is reinitiated.

In aspects of the invention, where the batch processing chamber is used in a CVD deposition mode, the precursor is continually delivered to the process volume 22a which is maintained at one or more processing pressures during the CVD process recipe step. The CVD process uses a mass transport limited reaction, rather than a reaction rate limited deposition process as used in an ALD process. In this CVD deposition configuration the pressure of the processing volume 22a can be varied in different phases of the CVD process step by varying the flow of a precursor or a carrier gas (e.g., argon, helium, etc.) into the process volume 22a, and/or controlling the exhaust flow rate to an external vacuum pump system (not shown). The exhaust flow rate can be controlled by restricting the exhaust flow to the external vacuum pump system by controlling the exhaust flow control devices 353 position (FIG. 12).

In one embodiment useful for the completion of ALD and CVD deposition processes, the process gas is a mixture of a carrier gas and a precursor “A”. The carrier gases are typically chosen based on the precursor “A”. For example, argon may be chosen as the carrier gas if the precursor “A” if a hafnium type precursor, such as, tetrakis-ethyl methyl amino hafnium (TEMAH), tetrakis-diethyl amino hafnium, (TDEAH), tetrakis-dimethyl amino hafnium (TDMAH), hafnium chloride (HfCl₄), Hf[N(C₃H₇)₂]₄, or Hf[N(C₄H₉)₂]₄, is used in the process. The carrier gases or purge gases may be an inert gas, such as argon, xenon, helium or nitrogen, and may be reactive or non-reactive with the precursor 122. Hydrogen may be a suitable carrier gas or purge gas in some embodiments of the invention.

One aspect of the invention is the way in which the batch process chamber, described herein, minimizes the use and thus waste of the often expensive precursor material. A TDMAH precursor currently is believed to cost about $10-$25/gram, which may translate to hundreds of dollars to deposit a 30 Å film on a batch of 25 substrates. The prior art batch chambers and a single substrate processing chamber both suffer from different defects which prevent them from minimizing the precursor waste like the embodiments of the invention disclosed herein. The precursor usage for a batch of substrates, for example 25 substrates, versus a single substrate processing chamber run multiple times (i.e., 25 times) will be less since the incremental increase in surface area of the chamber walls in the batch chamber, on which the precursor will deposit, is small compared with the surface area of a single substrate processing chamber coated multiple times. The prior art vertical diffusion furnace design is also more wasteful of the precursor gas since the bulk of the precursor flow is around the substrate support 12 and out the outlet 14, rather than flowing the precursor directly across the substrate surface, so more precursor needs to be dispensed to grow the same amount of film. Therefore, the use of a convective flow of the precursor gas over a batch of substrates can greatly reduce the precursor waste and thus reduce the process sequence and system COO.

In one embodiment the volume of the batch processing chamber is minimized to reduce the amount of wasted precursor and increase chamber throughput by reducing the process chamber process cycle time. One important aspect of an ALD process is the time in which it takes the substrate surfaces to be saturated with the precursor gas. In a traditional batch vertical diffusion furnace chamber, in which the process volume and chamber surface area tend to be large, it can take a significant amount of time to assure that all of the substrate and chamber surfaces are saturated with the precursor gas. Therefore, it is important to assure that the process volume is as small as possible to reduce precursor waste and reduce the time it takes to assure that all of the surfaces are saturated with the precursor gas. Various embodiments may able to achieve the reduction in precursor waste and batch processing time. For example, the volume of the processing area is not constrained, as in the prior art vertical diffusion furnace (VDF) processing chambers, by the need for the processing area to extend well past the length of the substrate support in a effort to account for the to the heat lost at the ends of the processing chamber. One embodiment, is adapted to improve upon the prior art by actively controlling the temperature of the substrates retained in the cassette 46 by use of heat generating devices (e.g., halogen lamps, resistive heaters), mounted on the sides and ends of the process volume 22a, temperature sensors (not shown), and a system controller 102 that are adapted to assure that the temperature of all areas of all of the substrates in the cassette 46 are at a uniform temperature. In one embodiment the volume during processing of the process volume 22a of the batch process chamber is minimized to a volume between about 0.5 liters per wafer and about 1.5 liters per wafer.

In another example of how the precursor waste and batch processing time can be reduced over the prior art configurations is the ability to minimize the diameter and length of the substrate processing region, or process volume 22a, since it is generally not constrained by the need to uniformly flow the process gases around the substrate support, as required in the prior art VDF, to assure that each substrate sees a uniform amount of the process gases.

In another example of how the precursor waste and batch processing time can be reduced over the prior art configurations is due to the increased throughput of the batch processing chamber is enhanced by the increased speed with which the process gases is able to saturate the substrate surface due to the substantially parallel injection of the process gases. The increased speed with which the precursor is able to saturate the surface of the substrate also reduces the chances of particle problems occurring due to the gas phase decomposition of the precursor gas, due to interaction of the precursor with the hot chamber walls prior to the surfaces being saturated. The throughput gain from the substantially parallel injection of the process gases can be realized since no time is wasted waiting to assure that all of the substrates in the batch have been exposed to the process gases long enough to saturate the substrate surface. This problem is commonly found in the prior art VDF processing chambers, as shown in FIG. 11, where the substrate closest to the gas inlet is exposed to the process gases longer than the last substrate in the substrate support 12, and thus the length of the process is limited by the time it takes the last substrate to form the desired deposited layer thickness. Aspects of the invention, may also improve upon the prior art since the distance from the injection point to the surface of the substrate is minimized thus reducing the chance that the precursor can suffer decomposition effects which causes the concentration of precursor to vary depending on the distance from the injector.

### Precursor Delivery System

Referring to FIG. 10, typically there are three ways the precursor “A” are processed to form a gas or vapor that can be delivered to a processing area of a processing chamber to deposit a layer of a desired material on a substrate. The first processing method is a sublimation process in which the precursor, which is in a solid form in the ampoule 520, is vaporized using a controlled process which allows the precursor to change state from a solid to a gas (or vapor) in the ampoule 520. The term gas, as used herein, is generally meant to describe a gas or a vapor. The second process used to generate a gas of a precursor “A” is by an evaporation process, in which a carrier gas is bubbled through a temperature controlled liquid precursor, and thus is carried away with the flowing carrier gas. The third, and final, process used to generate a precursor is a liquid delivery system in which a liquid precursor is delivered to a vaporizer by use of a pump 525, in which the liquid precursor changes state from a liquid to a gas by the addition of energy transferred from the vaporizer. The added energy is typically in the form of heat added to the liquid. In any of the three methods of described above for creating a precursor gas, it may be necessary to control the temperature of the ampoule 520 in an effort to regulate the vaporization process. Further description for controlling the temperature of the precursor within a vessel via a gradient temperature is in the commonly assigned U.S. patent application Ser. No. 10/447,255, entitled “Method and Apparatus of Generating PDMAT Precursor”, filed on May 27, 2003, and is herein incorporated by reference. The vessel and the precursor are maintained in a temperature range from about 25° C. to about 600° C., preferably in the range from about 50° C. to about 150° C.

FIG. 10 illustrates a schematic of one embodiment of a liquid delivery type gas source 501A that is used to deliver a process gas to the process volume 22a. The gas source 501A, in this embodiment, generally includes the following components: an ampoule gas source 512, an ampoule 520 containing a precursor “A”, a metering pump 525, a vaporizer 530, an isolation valve 535, a collection vessel assembly 540 and a final valve 503A. In one embodiment, the final valve 503A is designed to have a quick reaction time and linear process gas flow control to better control the mass injected into the process volume 22a when running an ALD process, minimize the burst of the injected process gas, and minimize the injection of an excessive amount of the process gas. The collection vessel assembly 540 generally includes the following components: an inlet 546, an outlet 548, a vessel 543, a resistive heating element 541 surrounding the vessel 543, a heater controller 542 and a sensor 544. In one embodiment, the sensor 544 includes two sensors, a temperature and a pressure sensor, for example, are attached to the vessel 543 to measure properties of the process gas(es) contained in the vessel 543. In one embodiment, a resistive heating element 541, one or more sensors 544, a heater controller 542 and a system controller 102 may be use to control the temperature of the gas or vapor residing in the vessel 543 to assure that gas or vapor in a desired state before it is delivered into the process volume 22a through the gas injection manifold assembly 200. The term “state” of the gas is generally defined as a condition of a gas or a vapor that can be characterized by definite quantities (e.g., pressure, temperature, volume, enthalpy, entropy). In one embodiment the heater controller 542 is part of the system controller 102.

Referring to FIG. 10, in one embodiment, the gas source 501A is adapted to deliver a process gas to the process volume 22a from the ampoule 520 containing a liquid precursor. To form a gas from a liquid precursor, the liquid precursor is vaporized by use of a metering pump 525 which pumps the precursor into the vaporizer 530, which adds energy to the liquid to cause it to change state from a liquid to a gas. In this embodiment, the metering pump 525 is adapted to control and deliver the liquid precursor at a desired flow rate set point throughout the process recipe step, by use of commands from the system controller 102. The vaporized precursor is then delivered to the collection vessel assembly 540 where it is stored until it is injected into the process volume 22a and across the surface of the substrates “W”. In one embodiment, the metering pump 525 is replaced with a liquid flow meter (not shown) and a gas source (e.g., element 512) to control the amount of liquid precursor delivered to the vaporizer 530. In this configuration a pressurized gas from the gas source is used to push the liquid precursor to the liquid flow meter which is adapted to meter, or control, the amount of liquid precursor to the vaporizer 530.

Since the precursor flow rate and amount of gas, or dose (or mass), can greatly affect the uniformity, repeatability and step coverage of a particular ALD or CVD process, the control of these parameters is very important to assure that the semiconductor fabrication process is repeatable and desirable device properties are achieved. One factor which can greatly affect the repeatability of a CVD or ALD process is the control of the precursor vaporization process. The control of precursor vaporization process is further complicated when it is used in batch type processes, since the amount of precursor, or dose, required to be delivered at any one time is larger, thus the fluctuations in mass flow rate is much larger than in a single substrate processing chamber. Batch delivery is further complicated by the need to achieve process results similar to those achieved in a single substrate process chamber to be competitive and the ever present threat of large number of substrates scrapped if the process varies out of a desired processing range. Also, the use of a liquid delivery system adds a further complication to an ALD or CVD process, since any interruption in the liquid precursor flow through the vaporizer can cause the mass flow rate of the precursor to vary wildly upon reinitiating flow, thus causing the mass flow rate and process results to vary. Stopping and starting the precursor flow can also cause dramatic pressure variations in the delivery line (e.g., pressure bursts), created by uneven vaporization, possibly causing damage to various components in the system and also possibly clogging of the vaporizer which will affect the repeatability of delivering the dose to the process volume 22a and the substrates. Therefore, it is desirable to always keep at least some amount of flow of precursor through the vaporizer to prevent uneven flow and clogging of the vaporizer. However, as noted above, the pressure and temperature of the process gas needs to be repeatable to assure that the process results do not vary from one substrate batch to another. To achieve consistent results, the vessel 543 which receives the vaporized precursor, and possibly an inert gas, is sized to collect and deliver a desired amount of a processing gas at a repeatable pressure and temperature.

One issue that may arise from the need to continually flow a liquid precursor through the vaporizer is created since the deposited film thickness may vary during different phases of a process recipe step or the timing of when the delivery of the dose is to occur can vary, thus mass and state of the gas in the vessel 543 may vary if a constant vaporization rate of the precursor is utilized during processing. To prevent this problem, in some embodiments it may be necessary to throw away (or dump) any excess precursor gas once a desired mass has been collected in the vessel 543. This process may be accomplished by monitoring the temperature and pressure of the process gas in the vessel 543 and then controlling the amount of excess gas that is purged by use the system controller 102 and a purge valve 537, which is connected to a waste collection system such as a conventional “scrubber.” One issue that arises is that the precursor is often expensive and thus dumping the excess material to the waste collection system can become very expensive and wasteful. Therefore, one aspect of the present invention utilizes the system controller 102 to control the vaporization rate, or flow of the liquid precursor through the vaporizer 530, depending on the projected amount of gas required and the timing of the delivery of the dose to the chamber. The system controller 102 thus projects the desired delivery time and amount (or dose) of gas required for the next process recipe step, by use of process sequence information, the calculated timing based on actual or prior experimental throughput information, or other user or system inputs. This feature is thus a predictive function that will vary the flow rate of the metered precursor to the vaporizer 530 as a function of time, to assure that the amount of gas and state of the gas is consistent when it is delivered to processing chamber.

### Precursor Recirculation System

Referring to FIG. 10A, in one embodiment, a precursor recirculation system 560 is added to the gas source 501 to reduce or eliminate the need to purge the excess precursor gas that is generated during the continuous flow of the liquid precursor though the vaporizer 530. The precursor recirculation system 560 generally contains system controller 102, an inlet line 562, a recirculation inlet valve 567, a recirculation outlet line 564, a recirculation outlet valve 566, an isolation valve 535, a recirculation collection vessel 561, a thermal control system 572 and a gas source 565. In this configuration once a desired mass has been delivered to the vessel 543 the system controller 102 opens the recirculation inlet line 562 by opening the recirculation inlet valve 567, closes the recirculation outlet line 564 by closing the recirculation outlet valve 566 and closes the isolation valve 535 so that the vaporized precursor flowing through the vaporizer 530 can be collected in the recirculation collection vessel 561. In some aspect of the invention, the temperature of the precursor gas collected in the recirculation collection vessel 561 is controlled by use of a thermal control system 572. The thermal control system 572 generally contains a temperature controller 563, one or more sensors 570, and heating/cooling elements 568 mounted inside or outside of the recirculation collection vessel 561. The heating/cooling elements 568 may be a thermoelectric devices, a resistive heaters, or other type of heat exchanging device. In one embodiment, the sensor 570 includes two sensors, a temperature and a pressure sensor, for example, are attached to the recirculation collection vessel 561 to measure properties of the process gas(es) contained in it. In one aspect of the invention the temperature of the precursor contained in the recirculation collection vessel 561 is maintained at a temperature below the precursor's condensation temperature to allow efficient collection of the precursor.

In one embodiment of the recirculation system 560, the precursor collected in the recirculation collection vessel 561 is used to fill the vessel 543 by closing the recirculation inlet valve 567, opening the recirculation outlet valve 566, closing an ampoule isolation valve 569 and pressurizing the recirculation collection vessel 561 by use of a gas source 565 which thus causes the liquid precursor “A” to flow into the vaporizer 530 and then into the vessel 543. In one embodiment, a recirculation metering pump (not shown) is added to the recirculation outlet line 564 to draw the liquid precursor from the recirculation collection vessel 561 and deliver it to the vaporizer 530 and the vessel 543. Once an amount of precursor has been delivered from the recirculation collection vessel 561, the system controller 102 may switch over to delivery of a liquid precursor from the ampoule 520 to prevent complete evacuation of the recirculation collection vessel 561.

In another embodiment, the precursor recirculation system 560 is used to provide a continual flow of a liquid precursor through the vaporizer 530 by continually recirculating an amount of a liquid precursor. The recirculation process is generally completed by causing an amount of a liquid precursor “A” retained in the recirculation collection vessel 561 to be injected into the vaporizer 530 which is then diverted to the recirculation collection vessel 561 where is chilled and recollected so that it can be redirected through the vaporizer 530. In one aspect of the invention a continuous flow of liquid precursor is maintained through the recirculation system 560, even while the vessel 543 is being filled, to prevent damage to the chamber hardware, generate particles and/or replenish a percentage of precursor in the recirculation collection vessel 561 with “fresh” precursor. In another aspect of the invention the recirculation process is stopped before, during or after the flow of the liquid precursor is initiated into the vaporizer 530 from the ampoule 520.

FIG. 10A illustrates one embodiment of the recirculation system 560 in which the collected precursor in the recirculation collection vessel 561 is diverted back to the ampoule 520 after an amount of precursor has been collected in the recirculation collection vessel 561. In this configuration the recirculation inlet valve 567 is closed, the recirculation outlet valve 566 is opened and the gas source 565 valve is opened to force the liquid precursor “A” to flow into the ampoule 520.

In one embodiment of the precursor delivery system, in which the precursor delivery is performed by a sublimation process or by an evaporation process, the system controller 102 is adapted to look ahead and adjust the vaporization rate as needed to assure that the vessel contains a desired mass of precursor at a desired time. This configuration is important since the precursor vaporization process, when using a sublimation or an evaporation process, has limitations on the maximum rate at which the precursor can be vaporized. The vaporization rate is generally limited by gas/liquid or gas/solid interface surface area, the temperature of the precursor, and the flow rate of the carrier gas delivered into the ampoule. Therefore, in one aspect of the invention the system controller 102 is adapted to adjust the time when to begin vaporizing and the rate of vaporization to prevent a case where the precursor delivery system cannot fill the vessel 43 in time due to need to vaporize the precursor at a rate that exceeds the maximum vaporization rate of the precursor delivery system.

### Exhaust Manifold Assembly

Referring to FIGS. 9 and 10, exhaust manifold assembly 300 includes an exhaust plate 352 having plurality of exhaust ports 354, an exhaust plenum 351, a control throttle valve 357, and gate valve 357 and is vacuum sealed to the other of walls 100b via an O-ring (not shown). The process gases are removed from process volume 22a through the plurality of ports 354 and are provided to exhaust plenum 351 via a plurality of associated exhaust flow control devices 353 which, in some embodiments, are similar to flow rate control devices 206. Process gases then flow through control throttle valve 357 and gate valve 356 to an external vacuum pump system (not shown). Exhaust plate 352 may be either cooled or heated via recirculating liquid or other means, depending upon the particular process employed. Note that for certain ALD or CVD processes it is desirable to heat the exhaust manifold assembly 300 (and thus exhaust ports 354) in order to minimize condensation thereon. Flow rate control devices 206, which in one embodiment may be a mechanical butterfly valve or needle valve, and the exhaust flow control devices 353 may be independently adjusted to allow for optimum process gas flow pattern or flow of the dose within the process volume 22a. In another aspect of the invention the exhaust plate 352 is temperature controlled by use of a temperature controlled heat exchanging fluid that flows through milled channels (not shown) in the exhaust plate 352.

### Thermal Control of a Batch Deposition Process

In an effort to form a uniform film having desirable film properties (e.g., good step coverage, minimize particles, crystalline or amorphous structure, stress, etc.) it is important to control the temperature of various components in the batch processing chamber. Four areas of the batch processing chamber that generally require temperature control are the substrate temperature by use of the heating structures 400, 501 and 550, the temperature of the chamber walls by use of one or more heat exchanging devices, the temperature of the components in the injection manifold assembly 200 by use of one or more heat exchanging devices, and the temperature of the components in the exhaust manifold assembly 300 by use of one or more heat exchanging devices. As noted above the control of the temperature of the substrates will have an affect on the film properties of the deposited film and thus is an important part of the batch ALD or batch CVD processes. Therefore, the control of the uniformity and set point temperature of the substrates in the cassette 46 are important aspects of the batch deposition process.

A second temperature controlled area of the batch processing chamber is the process volume walls (e.g., side walls 100a-b, top plate 32, circular seal plate 60, etc.) of the batch processing chamber. As noted above the control of the wall temperature may be completed using milled channels in the walls or heat generating deices that are in communication with the batch chamber walls. The temperature of the batch chamber walls is important to minimize the collection of unwanted byproducts on the walls and to assure no condensed precursor resides on the walls during subsequent processing steps in an effort to minimize process contamination and particle generation. In some cases it may be necessary for the wall temperature to be set high enough to allow a good quality film (e.g., non-particulating film) to be formed on the walls to minimize process contamination and particle generation.

A third temperature controlled area of the batch processing chamber is the injection manifold assembly 200. The injection manifold assembly's temperature may be controlled by use of milled channels in the injection manifold assembly 200 components or one or more heat generating devices (e.g., resistive heater elements, heat exchanger, etc.) (not shown) that are in communication with the various components. Typically all of the components in the injection manifold assembly 200 and the inlet lines 505A are heated to assure that an injected precursor does not condense and remain on the surface of these components, which can generate particles and affect the chamber process. It is also common to control the temperature of the injection manifold assembly 200 components below the precursor decomposition temperature to prevent gas phase decomposition and/or surface decomposition of the precursor on the surface of the various injection manifold assembly components which may “clog” the ports 208 in the injection plate 210.

A fourth temperature controlled area of the batch processing chamber is the exhaust manifold assembly 300. The exhaust manifold assembly's temperature may be controlled by use of milled channels in the exhaust manifold assembly 300 components or one or more heat generating devices (e.g., resistive heater elements, heat exchanger, etc.) (not shown) that are in communication with the various components. Typically all of the components in the exhaust manifold assembly 300 and the outlet line 355 are heated to assure that an injected precursor does not condense and remain on the surface of these components. It is also common to control the temperature of the exhaust manifold assembly 300 components below the precursor decomposition temperature to prevent deposition of the precursor on the surface of the various injection manifold assembly components and “clog” the exhaust ports 354 in the exhaust plate 352.

In one aspect of the invention, for example, a hafnium oxide deposition process is completed using a TDMAH precursor where the substrate temperature is maintained at a temperature between about 200 and about 300° C., the wall temperature is maintained at a temperature between about 80° C. and about 100° C., the injection manifold 200 temperature is maintained at a temperature between about 80° C. and about 100° C. and the exhaust manifold temperature 300 is maintained at a temperature between about 80° C. and about 100° C. In one aspect of the invention the substrate temperature is maintained at a temperature that is higher than the chamber walls (e.g., side walls 100a-b, top plate, etc.) which is maintained at a temperature higher than the exhaust manifold assembly 300 temperature, which is higher than the injection manifold assembly 200 temperature.

### Plasma Assisted ALD

In one embodiment, the batch processing chamber contains a capacitively or inductively coupled source RF source (not shown) to provide plasma bombardment before, during or after the deposition process is completed in the batch processing chamber. Typically RF frequency used to generate the plasma in the process volume 22a will be between about 0.3 MHz to greater than 10 GHz. Plasma bombardment of the film can affect the properties of the deposited film (e.g., film stress, step coverage, etc.). An exemplary apparatus and method of generating a capacitively coupled plasma in the batch processing chamber is further described in the U.S. patent application Ser. No. 6,321,680, entitled “Vertical Plasma Enhanced Process Apparatus and Method” filed Jan. 12, 1999, which is incorporated by reference herein to the extent not inconsistent with the claimed aspects and disclosure herein. In one embodiment, an inductive coil is mounted inside (or outside) the process volume 22a (not shown) in order to generate and control a plasma over the substrates. In one embodiment, a torroidal plasma source is adapted to the batch processing chamber to generate a plasma over the surface of the substrates. An exemplary torroidal source assembly is further described in U.S. patent application Ser. No. 6,410,449, entitled “Method Of Processing A Workpiece Using An Externally Excited Torroidal Plasma Source”, filed on Aug. 11, 2000, which is incorporated by reference herein to the extent not inconsistent with the claimed aspects and disclosure herein. In this embodiment one or more torroidal source conduits (not shown), in which a plasma is generated, are attached to one of the batch chamber walls 100b and the other side of the conduit is attached to an opposing wall 100b. Therefore, a plasma current can be generated which flows from one conduit across the substrate surfaces to the other side of the conduit.

In one embodiment, a plurality of biasing electrodes (not shown) may be embedded in the susceptor 62 to bias the substrate to promote plasma bombardment of the substrate surface during different phases of the deposition process. The biasing electrodes may be RF biased by use of second RF source (not shown) or they may be grounded in an effort to promote bombardment of the substrate surface.

### System Throughput Enhancement

As highlighted above, one aspect of the invention is the use of the batch chamber in conjunction with one or more single substrate processing chambers to increase the throughput of the system. The benefit of using one or more batch chambers can be truly realized where a batch chamber is used to complete one or more of the disproportionately long processing steps in a processing sequence, since the disproportionately long process step need only be completed once on all of the substrates in the batch.

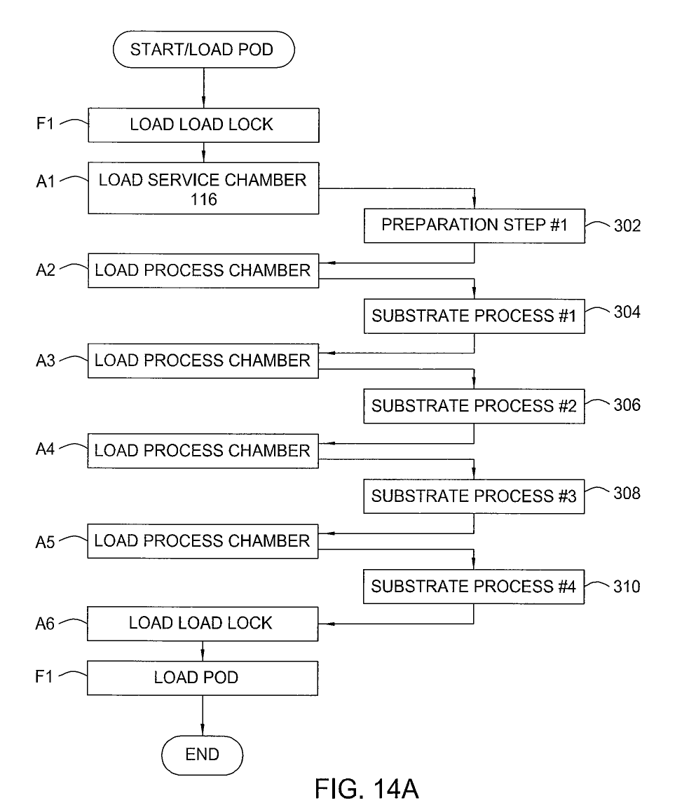

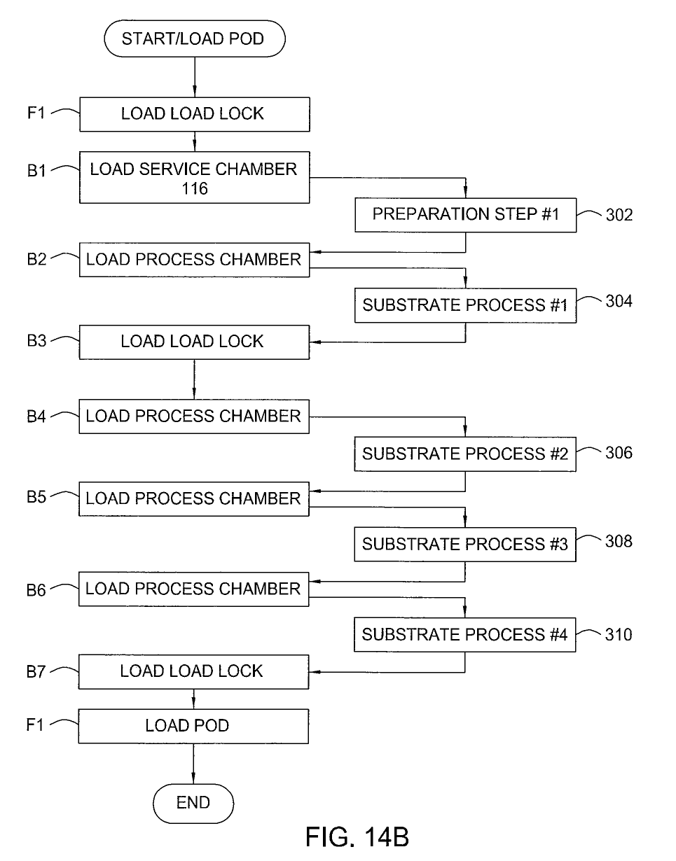

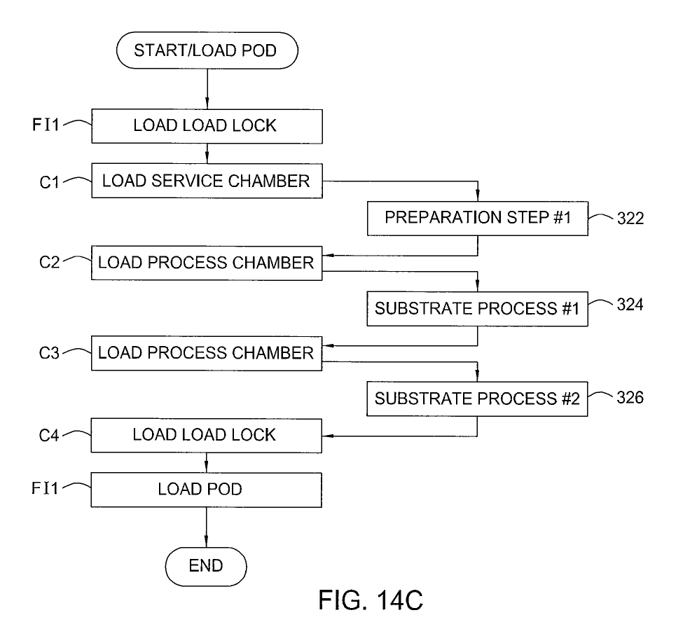

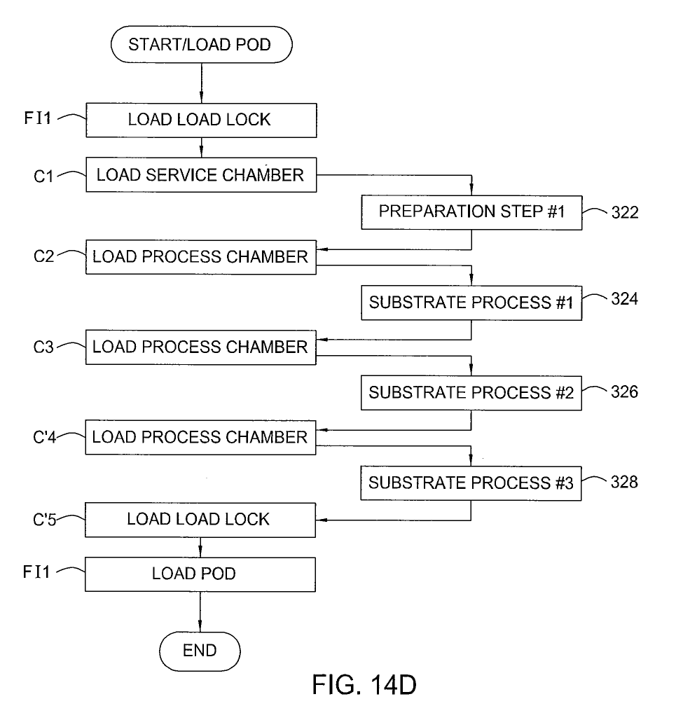

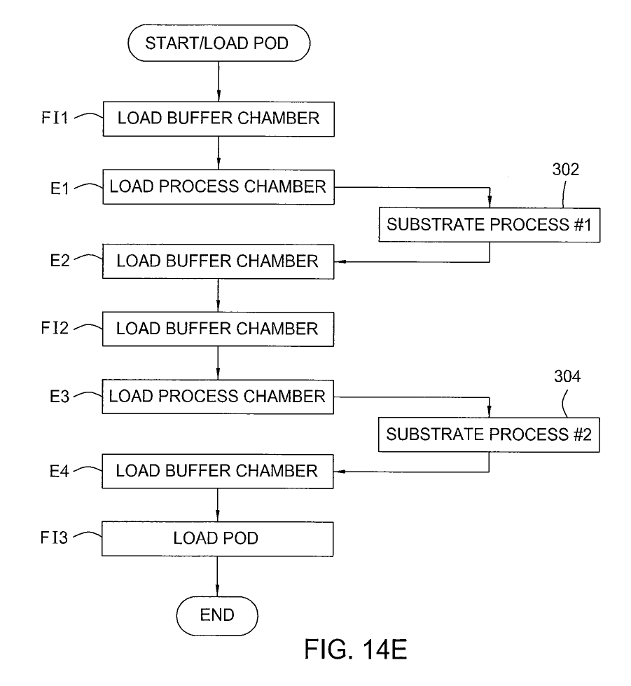

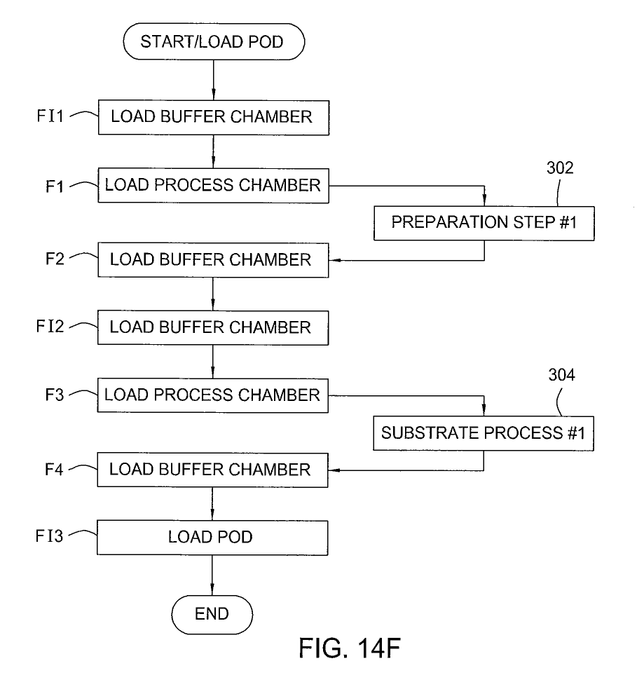

FIGS. 13A-C illustrate schematically various substrate transfer paths which the robot 113 and factory interface robots 108A-B used to transfer a substrate through a substrate processing sequence via commands from the system controller 102. A transfer path is generally a schematic representation of the path a substrate will travel as it is moved from one position to another so that various process recipe steps can be performed on the substrate(s). The associated process recipe step to match an associated position in the transfer path is shown in FIGS. 14A-F and is described below. The robot 113 and its associated components are not shown in FIGS. 13A-F for clarity, and thus more clearly illustrate the substrate transfer paths. The transfer paths shown in FIGS. 13A-F show possible transfer paths through a Centura RTM system, available from Applied Materials, Inc., but is not intended to limit the scope of the present invention since the shape of the cluster tool or number of processing stations is not limiting to the various aspects of the invention described herein. For example, in one embodiment, the use of a batch chamber in conjunction with one or more single substrate processing chamber may be used on an Endura RTM system, also available from Applied Materials, Inc. While FIGS. 13A-C all show a Substrate “W” being transferred from a pod, or FOUPS, placed in position 105A, this configuration is not intended to be limiting since a pod may be placed in any of pod positions 105A-D and either of the factory interface robots 108A-B can transfer the substrate to load locks 106A or 106B. In another embodiment, no factory interface is used and the substrates are directly placed into one of the load locks 106A-B by the user.

FIG. 13A illustrates one embodiment of a processing sequence wherein a substrate “W” is transferred through the cluster tool 100 following the substrate transfer paths A1-A6. The associated process recipe steps for the processing sequence shown in FIG. 13A is further illustrated in FIG. 14A. In this embodiment the substrate is removed from a pod placed in the position 105A and is delivered to load lock 106A following the transfer path FI1. In one embodiment, where the load lock 106A is a batch load lock, the factory interface robots 108A-B will load a load lock cassette (not shown) mounted in the load lock 106A until it is full and then by command from the system controller 102, the load lock 106A will close and pump down to a desirable base pressure so that the substrates can be transferred into the transfer chamber 110 which is already in a vacuum pumped down state. Once the load lock 106A has pumped down the substrate may optionally be transferred from the load lock 106A to the service chamber 116A following the transfer path A1, where a preparation step 302 (shown in FIG. 14A) is completed on the substrate. In another embodiment, the process sequence may skip the transfer path A1 and the associated preparation step 302. The preparation step 302 may encompass one or more preparation steps including, but not limited to substrate centerfinding, substrate orientation, degassing, annealing, substrate inspection, deposition and/or etching. After completing process recipe step 302 the substrate is then transferred to a processing chamber in position 114A, as shown in FIG. 13A, following the transfer path A2. In one embodiment, as shown in FIG. 13A, the first processing chamber is a batch processing chamber 201. In this case the system controller will load the batch processing chamber 201 with two or more substrates with each substrate being processed following the prior processing sequence steps, such as, following the A1 and A2 transfer paths shown in FIG. 13A and their associated process recipe step, for example, preparation step 302, as described in FIG. 14A. After performing the process recipe step 304 in the batch processing chamber 201 the substrates are sequentially processed in the single substrate processing chambers 202A through 202C following the transfer paths A3-A5 and their respective process recipe steps 306-310, as shown in FIGS. 13A and 14A. In one embodiment process recipe step 304 is a Hafnium oxide (HfOₓ) deposition step and/or an Al₂O₃ ALD deposition step. In one embodiment, process recipe steps 306 through 310 may be selected from one of the following processes RTP, DPN, PVD, CVD (e.g., CVD polysilicon, TEOS etc.), or metrology processing step.

Referring to FIGS. 13A and FIG. 14A, after the last process recipe step 310 has been completed on a substrate, the substrates will be loaded into the batch load lock following the transfer path A6. The process of loading the batch load lock is completed sequentially until all of the substrates have been processed and returned to the load lock 106A. Once all the substrates are returned to the load lock it will be vented to an atmospheric pressure and the substrates will be transferred to the pod by one of the factory interface robots 108A-B following the transfer path FI1. Other embodiments of the process sequence illustrated in FIG. 13A and 14A also include scenarios where the batch processing chamber may be the second or third process chambers in the processing sequence in which case the prior process sequence steps would be run on the substrates before they entered the batch processing chamber 201. In another embodiment, there are only two processing steps completed on the substrate after the batch processing step thus the transfer path A5 will deliver the substrate to the load lock 106A. In yet another embodiment there is only one processing steps completed on the substrate after the batch processing step thus the transfer path A4 will deliver the substrate to the load lock 106A.

FIG. 13B illustrates one embodiment of a processing sequence wherein a substrate “W” is transferred through the cluster tool 100 following the substrate transfer paths B1-B7. The associated process recipe steps for the processing sequence shown in FIG. 13B is further illustrated in FIG. 14B. In this embodiment the substrate is removed from a pod placed in the position 105A and is delivered to load lock 106A following the transfer path FI1. In a case where load lock 106A is a batch load lock, the system controller 102 will load the load lock cassette in load lock 106A (not shown) and pump down the load lock so that the substrates can be transferred into the mainframe 110. Once the load lock 106A has pumped down the substrate may optionally be transferred from the load lock 106A to service chamber 116A following transfer path B1, where a preparation step 302 is completed on the substrate. After the preparation step 302 has been completed the substrate is then transferred to a processing chamber mounted in position 114A-D. In one embodiment, the substrate is transferred to a processing chamber in position 114A, as illustrated in FIG. 13B, following the transfer path B2. In one embodiment, as shown in FIG. 13B, the first processing chamber is a batch processing chamber 201. In this case the system controller 102 will load the batch processing chamber 201 with two or more substrates following the B1 and B2 transfer paths shown in FIG. 13B and their associated recipe step 302 as illustrated in FIG. 14B. After process recipe step 304 has been completed in the batch processing chamber 201, the substrates are transferred back to the load lock 106A one-by-one, following the transfer path B3, until the batch processing chamber 201 is empty. Next the substrates housed in load lock 106A are then sequentially processed in the single substrate processing chambers 202A through 202C following the transfer paths B4-B6 and process recipe steps 306-308 and 310, as shown in FIGS. 13B and 14B, respectively. In one embodiment process recipe step 304 is a Hafnium oxide (HfOₓ) deposition step and/or an Al₂O₃ ALD deposition step. In one embodiment, process recipe steps 308 through 310 may be selected from one of the following processes RTP, DPN, PVD, CVD (e.g., CVD polysilicon, TEOS etc.), or metrology processing step.

Referring to FIGS. 13B and 14B, after the last process step has been completed on each of the substrates, the substrates are loaded into the batch load lock following the transfer path B7. Once all the substrates are returned the load lock 106A, the load lock is vented to an atmospheric pressure and the substrates will be transferred to the pod by one of the factory interface robots 108A-B following the transfer path FI1. The process sequence illustrated in FIG. 13B differs from the process sequence illustrated in FIG. 13A since the process sequence's action of unloading the batch processing chamber 201, frees the batch processing chamber 201 up so that substrates loaded into the load lock 106B from another pod mounted in one of the positions 105B-D, can loaded into the batch processing chamber 201 and processed while the subsequent processes 202A-C are completed on the substrates originally loaded into load lock 106A. In other embodiments the process sequences may have fewer process sequence steps then that shown in FIGS. 13B and 14B.

FIG. 13C illustrates one embodiment of a processing sequence wherein a substrate “W” is transferred through the cluster tool 100 following the substrate transfer paths C1-C4. The associated processing steps for the processing sequence shown in FIG. 13C is further illustrated in FIG. 14C. In this embodiment the substrate is removed from a pod placed in the position 105A and placed in load lock 106A following the transfer path FI1. In a case where load lock 106A is a batch load lock the factory interface robots 108A-B will load a load lock cassette (not shown) mounted in the load lock 106A until it is full and then it is pumped down. Once the load lock 106A has pumped down the substrate may optionally be transferred from the load lock 106A to service chamber 116A or 116B, following the transfer path C1, where one or more preparation steps 322 are completed on the substrate. After processing, the substrate is then transferred to a processing chamber mounted in position 114C or 114D following the transfer path C2. In one embodiment, as shown in FIG. 13C, the first processing chamber is a single substrate processing chamber 202A or 202B where a substrate processing step 324 may be performed on the substrate. In one embodiment the substrate processing step 324 may encompass one or more process recipe steps including, but not limited to substrate degassing, annealing, preclean, metrology or substrate inspection, deposition and/or etching. A pre-clean chamber, such as the Pre-Clean II Chamber™ available from Applied Materials, Inc., Santa Clara, Calif., cleans the substrates by removing the undesired layer of oxides. After being processed in one of the processing chambers 202A or 202B, the substrate is then transferred to the batch processing chamber 201 following transfer path C3. In this case the system controller will load the batch processing chamber 201 with two or more substrates that have been processed following the transfer paths C1 and C2, as shown in FIG. 13C, and recipe steps 322 and 324 as described in FIG. 14C. The process recipe step 326 is then completed on the substrates in the batch processing chamber 201. In one embodiment, process recipe steps 326 is a Hafnium oxide (HfOₓ) deposition step and/or an Al₂O₃ ALD deposition step.

In one embodiment of the process sequence illustrated in FIGS. 13C and 14C the first substrate process, performed in the single substrate processing chamber 202A or 202B, is a preheat process where a substrate is preheated to a desired temperature before it is placed in the batch processing chamber 201. Use of this processing sequence can minimize the time required to stabilize the substrate temperature in the batch processing chamber 201 prior to starting the batch wafer process, and thus can enhance the process sequence throughput. This process sequence is important in cases where the batch process is intended to be run at temperatures below about 350° C., since the ability to transfer heat to the substrates by a radiation heat transfer method is not efficient at these low processing temperatures. An exemplary preheating process may be, for example, preheating the substrates to a temperature of about 250° C. prior to processing the substrates in the batch processing chamber at a temperature of about 250° C. In one aspect of the invention the single substrate processing chamber is replaced with a batch substrate preheat chamber (not shown) which is adapted to preheat two or more substrates at one time to a desired preheat temperature.

In one embodiment, the preheat process is performed in the batch load lock chamber 106 before the substrates are placed into the batch processing chamber 201. In one aspect of the invention the substrates can be preheated in the batch load lock chamber after the chamber is pumped down by use of a radiation heat transfer method (e.g., lamps, resistive heaters, etc.) or a by flowing a heated purge gas (e.g., argon, etc.) across the surface of the substrates retained in a batch load lock cassette. In another aspect of the invention, the batch load lock may be fitted with a load lock cassette including a plurality of heat conductive shelves that are adapted to preheat the substrates retained therein. In one embodiment, after being preheated in the batch load lock 106 the substrate is processed in one or more single substrate processing chamber 202A before it is placed in the batch processing chamber 201.

In one embodiment of the cluster tool 100, a preheating position or preheat chamber (not shown) is positioned between a transfer chamber 110 and the batch processing chamber 201. In another embodiment of the cluster tool 100, a preheating position or preheat chamber is positioned between front-end environment 104 and the batch processing chamber 201. For example, as illustrated in FIG. 2C, the cool down plate 153 in the buffer/cool down position 152 is adapted to preheat the substrates prior placement of the substrate in the batch processing chamber 201. In one embodiment, the buffer/cool down position 152 is adapted to preheat the substrates prior placement of the substrate in the batch processing chamber 201 and also adapted to cool the substrates after processing in the batch processing chamber 201. In this configuration the buffer/cool down position 152 may use a thermoelectric device or a temperature controlled fluid heat exchanging body to heat and/or cool the substrates.

Referring to FIGS. 13C and 14C, the substrates are then transferred back to the load lock 106A, following the transfer path C4, until the batch processing chamber 201 is empty. Once all the substrates are returned the load lock will be vented to an atmospheric pressure and the substrates will be transferred to the pod one by one following the transfer path FI1.

In one embodiment, a processing step 328 is added to the processing sequence shown in FIG. 13C, which is further illustrated in FIGS. 13D and 14D. In this embodiment the substrate is transferred to the post batch processing chamber following transfer path C4′ after being processed in the batch processing chamber 201. After the process recipe step 328 is completed in the processing chamber 202D the substrates are transferred to the load lock 106A following transfer path C5′.

FIGS. 13E and 13F illustrates two different process sequences that can be used in conjunction with the cluster tool 100 shown in FIG. 2C. FIG. 13E illustrates one embodiment of a processing sequence wherein a substrate “W” is transferred through the cluster tool 100 following the substrate transfer paths E1-E4 and FI1-FI3. The associated processing steps for the processing sequence shown in FIG. 13E is further illustrated in FIG. 14E. In this embodiment, the substrate is removed from a pod placed in the position 105A and placed in the buffer/cool down position 152A of the chamber 150A attached to the batch substrate processing chamber 201, by following the transfer path FI1. After the substrate is dropped off at the buffer/cool down position 152A the substrate transfer mechanism 154A transfers the substrate into the attached batch processing chamber 201 following transfer path E1. The system controller 102 may load the batch processing chamber 201 with two or more substrates following the transfer paths FI1 and E1 shown in FIG. 13E. After the batch processing step 304 has been completed in the batch processing chamber 201, the substrate is then transferred to the buffer/cool down position 152A following the transfer path E2 where the substrate can be cooled so that it can be transferred to the next processing step. The substrate is then transferred from the buffer/cool down position 152A to the buffer/cool down chamber 152B following transfer path FI2. After the substrate is dropped off at the buffer/cool down position 152B the substrate transfer mechanism 154B transfers the substrate into the attached single substrate processing chamber 202A following transfer path E3. After the single substrate processing step 306 has been completed in the single substrate processing chamber 202A, the substrate is then transferred to the buffer/cool down position 152B following the transfer path E4 where the substrate may be cooled so that it can be transferred to pod following transfer path FI3.

FIG. 13F illustrates the transfer of the substrate into single substrate processing chamber 202A. FIG. 13F illustrates one embodiment of a processing sequence wherein a substrate “W” is transferred through the cluster tool 100 following the substrate transfer paths F1-F4 and FI1-FI3. The associated processing steps for the processing sequence shown in FIG. 13F is further illustrated in FIG. 14F. In this embodiment, the substrate is removed from a pod placed in the position 105B and placed in the buffer/cool down position 152B of the chamber 150B attached to the single substrate processing chamber 202A, by following the transfer path FI1. After the substrate is dropped off at the buffer/cool down position 152B the substrate transfer mechanism 154B transfers the substrate into the attached single substrate processing chamber 202A. After the single substrate processing step 304 has been completed in the batch processing chamber 202A, the substrate is then transferred to the buffer/cool down position 152B following the transfer path F2 where the substrate may be cooled so that it can be transferred to the next processing step. The substrate is then transferred from the buffer/cool down position 152B to the buffer/cool down chamber 152A following transfer path FI2. After the substrate is dropped off at the buffer/cool down position 152A the substrate transfer mechanism 154A transfers the substrate into the attached batch processing chamber 201 following transfer path F3. The system controller 102 may load the batch processing chamber 201 with two or more substrates following the transfer paths FI1, F1-F2, FI2, and F3 as shown in FIG. 13F. After the processing step 306 has been completed in the batch processing chamber 201, the substrate is then transferred to the buffer/cool down position 152A following the transfer path F4 where the substrate may be cooled so that it can be transferred to pod following transfer path FI3.

In one aspect of the invention, as illustrated in FIGS. 2C-E and 13E-F, the system controller 102 is adapted to monitor the queue time of the substrates after they are exposed to atmosphere after being processed in a first processing chamber (e.g., single substrate processing chamber 202A or batch processing chamber 201) and before they are processed in the next processing recipe step. For example, the embodiment shown in FIG. 13E, the system controller 102 may start timing of the exposure of the substrate from the time it is placed in the buffer/cool down chamber 152A until the substrate is placed in the single substrate processing chamber 202A (e.g., transfer path steps E2, FI2 and E3), and thus will not place the substrate in the buffer/cool down position 152A until the single substrate processing chamber 202A is ready to accept a substrate. In this way the amount of time the substrate is exposed to contaminants is minimized in between the two process recipe steps (e.g., processing step 304 and processing step 306).

### Process Recipe Sequences

### Hafnium Oxide/Aluminum Oxide Capacitor Stack Example

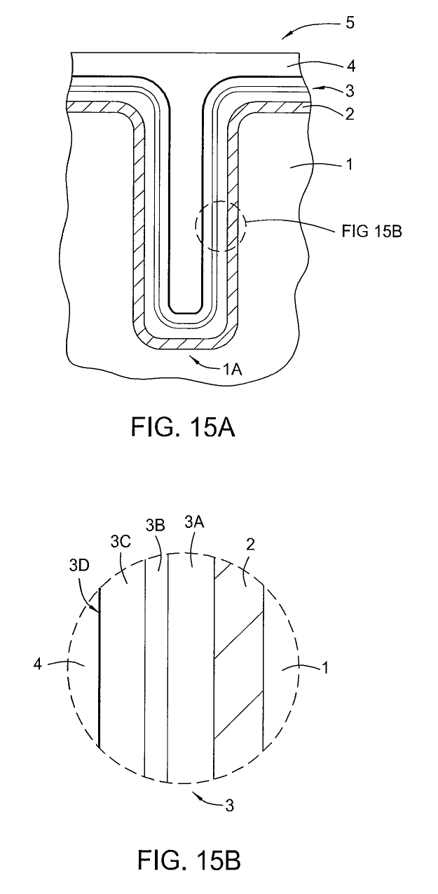

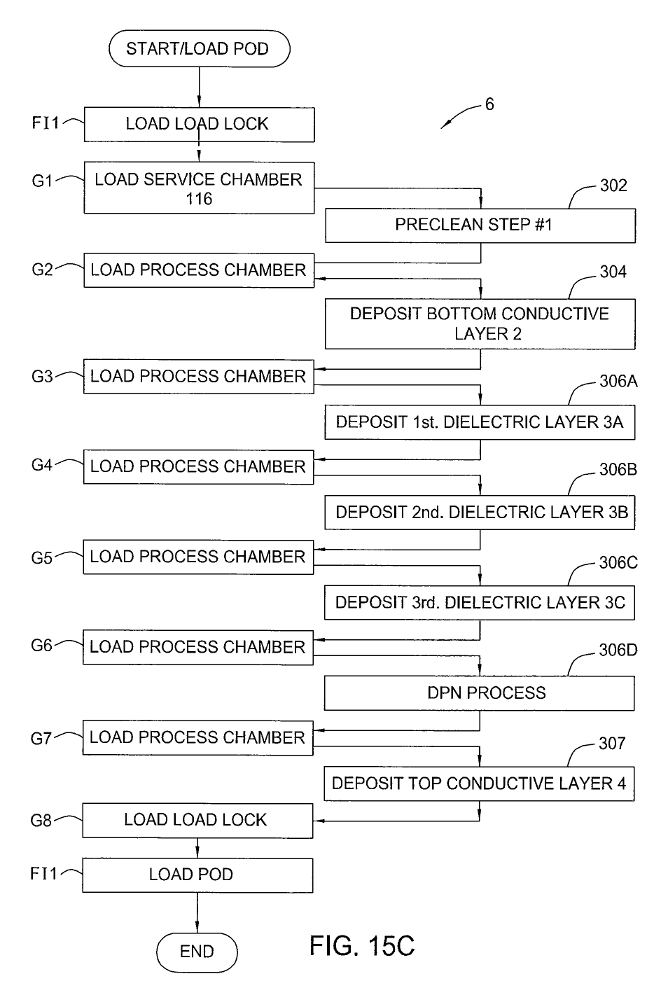

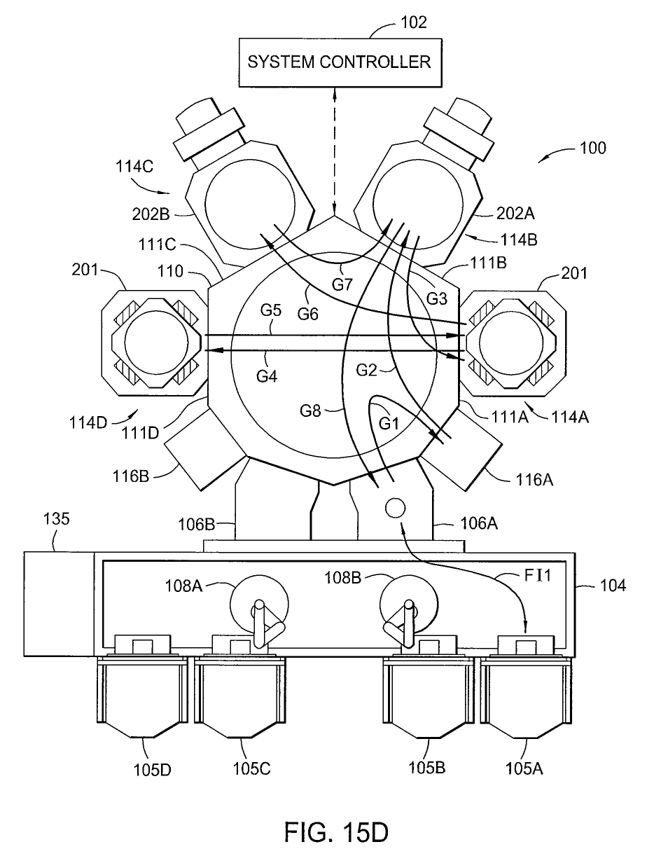

FIGS. 15A and 15B illustrate a cross-sectional view of capacitor structure 5 that can be fabricated using a processing sequence 6 that utilizes aspects of the invention. In one embodiment, the process sequence used to fabricate the capacitor structure 5, as discussed below, may be completed on a cluster tool 100 similar to the configuration illustrated in FIG. 2B, following the transfer paths shown in FIG. 15D. The capacitor structure 5 generally contains a substrate 1, bottom conductive layer 2, a dielectric layer 3 and a top conductive layer 4. In one embodiment, prior to processing a trench 1A is formed in the substrate using conventional lithography and etching techniques such that the trench 1A is formed in a surface of the substrate 1. After the trench 1A is formed in one or more of the substrates they are brought to the cluster tool 100 such that the layers 2-4 can be formed on the substrate surface by following the process sequence shown in FIG. 15C and following the transfer paths (elements G1-G8) shown in FIG. 15D. The substrate is first oriented in the service chamber 116A (or 116B not shown) and degassed using IR lamps mounted in the service chamber 116A. In one aspect of the invention a preclean process step 302 may be completed on the substrate in the service chamber 116A, to remove any surface contamination.

The second process recipe step 304 in the process sequence 6 is the deposition of the bottom conductive layer 2 on the surface of the substrate 1 and in the trench 1A. The process recipe step 304 may be completed in a single substrate processing chamber 202A where 1000 A of a metal, for example, tantalum, tantalum nitride, tungsten, titanium, platinum, titanium nitride, a doped poly-silicon or ruthenium is deposited using a CVD, PVD or ALD deposition process. Prior to performing the process recipe step 304 the substrate is transferred from the service chamber 116A to the single substrate processing chamber 202A following the transfer path G2.

The next process recipe steps 306 (i.e., 306A-D) are implemented to deposit one or more layers of one or more dielectric materials to help form the dielectric layer 3 of the capacitor structure 5. FIGS. 15A and 15B illustrate one aspect of the invention where three dielectric layers (i.e., 3A-C) have been deposited on the bottom conductive layer 2 and a final surface treatment process 3D was performed on the top most layer of the last dielectric layer 3C. The number and thickness of the dielectric layers deposited on a substrate surface can be varied as required to meet the device performance requirements and thus the description or illustration of the process sequence described herein is not intended to limit the scope of the invention.

The third process recipe step 306A, deposits a first dielectric layer 3A on the bottom conductive layer 2 using a CVD or ALD processing technique. For example, the first dielectric layer 3A is a 30 Å thick hafnium oxide or a hafnium silicate (i.e., hafnium silicon oxide) layer deposited using an ALD type process. Since hafnium oxide or hafnium silicate deposition rate is slow, for example, the time to deposit 30 Å can take on the order of about 200 minutes, this disproportionately long process step is completed in the batch processing chamber 201A. Therefore to maximize the cluster tool throughput the batch processing chamber 201A is loaded with two or more substrates that have completed the first and second process recipe steps 302 and 304 prior to starting the batch processing step 306A. An example of an exemplary method of forming an ALD hafnium oxide or hafnium silicate film is further described in the U.S. Provisional Application Ser. No. 60/570,173 [APPM 8527L], entitled “Atomic Layer Deposition of Hafnium-Containing High-K Materials”, filed May 12, 2004, which is incorporated by reference herein to the extent not inconsistent with the claimed aspects and disclosure herein. Prior to performing the process recipe step 306 the substrate is transferred from the single substrate processing chamber 202A to the first batch processing chamber 201A following the transfer path G3.

The fourth process recipe step 306B, deposits a second dielectric layer 3B on the first dielectric layer 3A using an CVD or ALD processing technique. For example, the second dielectric layer 3B is a 30 Å thick aluminum oxide layer deposited using an ALD type process. While FIGS. 15C and 15D illustrates the process of transferring the substrates from the first batch chamber 201A to the second batch chamber 201B to minimize any process interaction or contamination concerns. In one embodiment both deposition processes (e.g., 306A and 306B) are completed in the same batch processing chamber. Since the ALD aluminum oxide process deposition rate is slow, for example, the time to deposit 30 Å can take about 20-45 minutes, this disproportionately long process step is completed in the batch processing chamber 201B. Therefore, to maximize the cluster tool throughput the batch processing chamber 201B is loaded with two or more substrates that have completed the first, second and third process recipe steps 302, 304 and 306A prior to starting the batch processing step 306B. An example of an exemplary method of forming an ALD aluminum oxide film is further described in the U.S. patent application Ser. No. 10/302,773 [APPM 6198], entitled “Aluminum Oxide Chamber and Process”, filed Nov. 21, 2002, which is incorporated by reference herein to the extent not inconsistent with the claimed aspects and disclosure herein. Prior to performing the process recipe step 306B the substrate is transferred from the first batch processing chamber 201A to the second batch processing chamber 201B following the transfer path G4.

The fifth process recipe step 306C, deposits a third dielectric layer 3C on the second dielectric layer 3B using a CVD or ALD processing technique. For example, the first dielectric layer 3A is a 30 Å thick hafnium oxide or a hafnium silicate layer deposited using an ALD type process. Since hafnium oxide or hafnium silicate deposition rate is slow, to avoid any cross contamination of the batch processing chamber 201B, this disproportionately long process step is completed in the batch processing chamber 201A. Therefore to maximize the cluster tool throughput the batch processing chamber 201A is loaded with two or more substrates that have completed the first, second, third and fourth process recipe steps 302, 304, 306A, and 306B prior to starting the batch processing step 306C. Prior to performing the process recipe step 306C the substrate is transferred from the second batch processing chamber 201B to the first batch processing chamber 201A following the transfer path G5.

The sixth process recipe step 306D, is a plasma nitridation process step completed in a single substrate processing chamber 202B which is configured to sequentially perform a DPN processing technique on the surface of the third dielectric layer 3C. For example, the substrate is transferred to a DPN chamber, such as the CENTURA™ DPN chamber, available from Applied Materials, Inc., located in Santa Clara, Calif. During the DPN process, the dielectric layer 3C is bombarded with atomic-N formed by co-flowing N₂ and a noble gas plasma, such as argon. Besides N₂, other nitrogen-containing gases may be used to form the nitrogen plasma, such as NH₃, hydrazines (e.g., N₂H₄ or MeN₂H₃), amines (e.g., Me₃N, Me₂NH or MeNH₂), anilines (e.g., C₆H₅NH₂), and azides (e.g., MeN₃ or Me₃SiN₃). Other noble gases that may be used in a plasma process include helium, neon and xenon. The length of the nitridation process can be between about 10 seconds and about 120 seconds. The nitridation process is typically conducted at a plasma power setting from about 900 watts to about 2,700 watts and a process pressure at about 10 mTorr to about 100 mTorr. The nitrogen has a flow from about 0.1 slm to about 1.0 slm, while the noble gas has a flow from about 0.1 slm to about 1.0 slm. In a preferred embodiment, the nitridation process is a DPN process and includes a plasma by co-flowing Ar and N₂. Prior to performing the process recipe step 306D the substrate is transferred from the first batch processing chamber 201B to the second single substrate processing chamber 202B following the transfer path G6.

The seventh, and final, process recipe step 307 in the process sequence 6 is the deposition of the top conductive layer 4 on the surface of the dielectric layer 3 to fill the remainder of the trench 1A. The process recipe step 307 may be completed in a single substrate processing chamber 202A where top conductive layer 4, for example, tantalum, tantalum nitride, tungsten, platinum, titanium, titanium nitride, a doped poly-silicon or ruthenium is deposited using a CVD, PVD or ALD deposition process. Prior to performing the process recipe step 307 the substrate is transferred from the second single substrate processing chamber 202B to the single substrate processing chamber 202A following the transfer path G7. The substrate(s) are then transferred from the single substrate processing chamber 202A to pod 105A following the transfer paths G8 and FI1.

While the foregoing is directed to embodiments of the present invention, other and further embodiments of the invention may be devised without departing from the basic scope thereof, and the scope thereof is determined by the claims that follow.

What is claimed is:

1. A method of processing a substrate, comprising:
loading two or more substrates into a batch load lock chamber of a cluster tool, wherein the cluster tool comprises:
the batch load lock chamber;
a batch processing chamber;
a first single-substrate processing chamber; and
a transfer chamber, wherein the transfer chamber is connected to the batch processing chamber, the first single-substrate processing chamber, and the batch load lock chamber;
transferring the two or more substrates to the batch processing chamber;
performing a first process recipe on the two or more substrates in the batch processing chamber;
transferring the two or more substrates from the batch processing chamber to the batch load lock chamber; and
sequentially transferring each of the two or more substrates to the first single-substrate substrate processing chamber, where a second process recipe is completed on each of the two or more substrates.

2. The method of claim 1, further comprising transferring the each of the two or more substrates back to the batch load lock chamber after completion of the second process recipe.

3. The method of claim 2, wherein the first process recipe comprises:
rotating the two or more substrates by use of a rotation motor;
controlling the radiant energy delivered to the two or more substrates; and
depositing a thin film by injecting a mass of a precursor containing gas or vapor across the surface of the two or more substrates.

4. The method of claim 3, wherein the thin film comprises hafnium oxide formed by atomic layer deposition.

5. The method of claim 3, wherein the thin film comprises aluminum oxide formed by atomic layer deposition.

6. The method of claim 1, further comprising preparing the two or more substrates prior to the first process recipe by transferring the two or more substrates from the batch load lock chamber to a service chamber connected to the transfer chamber.

7. The method of claim 6, wherein the preparing the two or more substrates comprises one of more of substrate centering, substrate orientation, degassing, annealing, inspection, deposition and etching.

8. The method of claim 1, wherein the cluster tool system further comprises a factory interface connected to the batch load lock chamber, and loading two or more substrates into the batch load lock is completed by a factory interface robot mounted in the factory interface.

9. The method of claim 1, wherein the first single-substrate processing chamber is adapted to perform an RTP process, a CVD process, a PVD process, a DPN process or a metrology process.

10. A system for processing substrates, comprising:
a factory interface having a transfer region connecting to a plurality of pods configured to receive cassettes;
at least one batch processing chamber configured to simultaneously process a plurality of substrates, wherein the at least one batch processing chamber is connected with the factory interface; and
at least one single-substrate processing chamber configured to process one substrate a time, wherein the at least one single-substrate processing chamber is connected with the factory interface.

11. The system of claim 10, further comprising:
a transfer chamber connected to the at least one batch processing chamber and the at least one single-substrate processing chamber, wherein the transfer chamber is connected with the factory interface; and
a transfer robot disposed in the transfer chamber, wherein the transfer robot is configured to transfer substrates between the at least one batch processing chamber and the at least one single-substrate processing chamber.

12. The system of claim 11, further comprising:
a first batch load lock chamber connecting the transfer chamber and the factor interface; and
a second batch load lock chamber connecting the transfer chamber and the factory interface, wherein the transfer robot is configured to transfer a plurality of substrates from and to the first and second batch load lock chambers.

13. The system of claim 12, further comprising one or more service chambers connected to the transfer chamber, wherein the one or more service chambers are adapted for degassing, orientation, or cooling down.

14. The system of claim 11, wherein the transfer chamber is directly connected to the factory interface, and the transfer robot in the transfer chamber is configured to directly exchange substrate with a factory interface robot disposed in the factory interface.

15. The system of claim 10, further comprising:
a first buffer chamber connected between the factory interface and each of the at least one batch processing chamber; and
a second buffer chamber connected between the factory interface and each of the at least one single-substrate processing chamber.

16. A method of processing a substrate, comprising:
transferring two or more substrates to a batch load lock chamber of a cluster tool, wherein the cluster tool comprises:
the batch load lock chamber;
a factory interface connecting the batch load lock chamber and a plurality of PODs;
a batch processing chamber;
a first single-substrate processing chamber; and
a transfer chamber connected to the batch load lock chamber, the batch processing chamber, and the first single-substrate processing chamber;
transferring the two or more substrates to the batch processing chamber, where a first process recipe is completed on the two or more substrates;
transferring the two or more substrates from the batch processing chamber to the batch load lock chamber;
sequentially transferring each of the two or more substrates to the first single substrate processing chamber, where a second process recipe is completed on each of the two or more substrates; and
sequentially transferring each of the two or more substrates back to the batch load lock after the second process recipe is completed on each of the two or more substrates.

17. The method of claim 16, wherein the first processing step comprises:
rotating the two or more substrates by use of a rotation motor;
controlling the radiant energy delivered to the two or more substrates; and
depositing a film by flowing a processing gas across surfaces of the two or more substrates.

18. The method of claim 17, wherein the film is one of aluminum oxide and aluminum oxide deposited by an atomic layer deposition process.

19. The method of claim 18, wherein the second process recipe is selected from an RTP process, a CVD process, a PVD process, a DPN process or a metrology process.

20. The method of claim 19, wherein the CVD process is a polysilicon deposition process.
